(19) United States
(12) Patent Application Publication
(10) Pub. No.: US 2008/0024041 A1
(43) Pub. Date: Jan. 31, 2008

(54) THIN FILM PIEZOELECTRIC RESONATOR AND MANUFACTURING METHOD THEREOF

(75) Inventor: Hironobu SHIBATA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/778,352

(22) Filed: Jul. 16, 2007

(30) Foreign Application Priority Data
Jul. 27, 2006 (JP) 2006-205277

(51) Int. Cl. H03H 9/17; H01L 41/00; H01L 41/08; H03H 3/02

(52) U.S. Cl. 310/340; 29/25.35

(57) ABSTRACT

A thin film piezoelectric resonator, includes: a sealing member; an insulating layer with fine holes which is provided on the sealing member; a semiconductor layer which has a cavity over the fine holes provided on the insulating layer; a protective film provided on the semiconductor layer and over the cavity; a lower electrode provided on the protective film; a piezoelectric film provided on the lower electrode; an upper electrode provided on the piezoelectric film; a first lead electrode connected to the lower electrode and provided on the protective film; a second lead electrode connected to the upper electrode and provided on the protective film; and an etched part of the protective film or a deposited layer part which is formed opposite the fine holes.

### CROSS-REFERENCE TO RELATED APPLICATIONS

This application is based upon and claims the benefit of priority from the prior Japanese Patent Application No. 2006-205277, filed on Jul. 27, 2006; the entire contents of which are incorporated herein by reference.

### BACKGROUND OF THE INVENTION

The present invention relates to a thin film piezoelectric resonator and manufacturing method thereof, and in particular relates to a thin film piezoelectric resonator wherein a thin film piezoelectric resonator cavity is formed and the frequency is adjusted, as well as to a manufacturing method thereof.

A thin film piezoelectric resonator that uses the thickness longitudinal resonance of a piezoelectric film is also referred to as a FBAR (Film Bulk Acoustic Resonator) or a BAW (Bulk Acoustic Wave) element or the like. Thin film piezoelectric resonators are extremely small devices which have sharp resonating characteristics and high excitation efficiencies above the gigahertz regions, and this technology is anticipated to be useful for applications in RF filters for mobile radios and voltage controlled oscillators.

With thin film piezoelectric resonators, the resonance frequency is determined by the speed of sound and film thickness of the piezoelectric body, and normally 2 GHz is achieved with thin film between 1 μm and 2 ηm, and 5 GHz is achieved with thin film between 0.4 μm and 0.8 μm, and high-frequencies in the several tens of GHz range are also possible.

The film thickness precision required for piezoelectric films and the electrodes or the like of a thin film piezoelectric resonator is so high that achieving this precision is difficult even with a conventional semiconductor film forming device or a thin film piezoelectric resonator device. Therefore, the film thickness or the mass must be adjusted at a stage after film forming and after forming and measuring the element and the like. An example of the conventional method is a method where a thin passivation film or the like that covers the top of a thin film piezoelectric resonator is carefully removed or added while the entire surface of a thin film piezoelectric resonator is exposed (for example, refer to the Japanese Unexamined Patent Application Publication No. 2003-264445). The order varies depending on the density of the substance, but adjusting on the order of several nanometers will induce a change of several megahertz, so in order to make adjustments smaller than plus or minus 1 MHz, adjustments on the angstrom level are required, and currently this is extremely difficult to achieve. Therefore, precision on a level of several layers of atoms is required to adjust the frequency of thin film piezoelectric resonators. However, when physically etching an adjustment film that is placed directly on a thin film piezoelectric resonator or when placing a substance as a weight over the thin film piezoelectric resonator, fine adjustments are extremely difficult.

For example, when argon ion beam etching is performed to a thin passivation film that coats the top of a thin film piezoelectric resonator while the entire surface of the thin film piezoelectric resonator is exposed, exceeding the etching amount can easily occur, and therefore excessively increasing the resonance frequency of the thin film piezoelectric resonator can easily occur.

On the other hand, when a deposition layer is deposited on a thin passivation film that covers the top of a thin film piezoelectric resonator when the entire surface of the thin film piezoelectric resonator is exposed, exceeding the deposition amount can easily occur, and therefore excessively reducing the resonance frequency of the thin film piezoelectric resonator can easily occur.

### SUMMARY OF THE INVENTION

According to an aspect of the invention, there is provided a thin film piezoelectric resonator, including: a sealing member; an insulating layer with fine holes which is provided on the sealing member; a semiconductor layer which has a cavity over the fine holes provided on the insulating layer; a protective film provided on the semiconductor layer and over the cavity; a lower electrode provided on the protective film; a piezoelectric film provided on the lower electrode; an upper electrode provided on the piezoelectric film; a first lead electrode connected to the lower electrode and provided on the protective film; a second lead electrode connected to the upper electrode and provided on the protective film; and an etched part of the protective film or a deposited layer part which is formed opposite the fine holes.

According to an aspect of the invention, there is provided a thin film piezoelectric resonator, including: a lower electrode; a piezoelectric film provided on the lower electrode; an upper electrode provided on the piezoelectric film; a protective film provided on the upper electrode; an upper member having fine holes provided on the protective layer with a cavity therebetween; a sealing member which seals the cavity and is provided on the upper member; and an etched part of the protective film or a deposited layer part which is formed opposite the fine holes.

According to an aspect of the invention, there is provided a manufacturing method for a thin film piezoelectric resonator, including: forming a structure having a multilayer structure including a first protective film, a lower electrode, a piezoelectric film, an upper electrode and a second protective film in this order, a first lead electrode connected to the lower electrode, a second lead electrode connected to the upper electrode, and a member having fine holes opposite to the multilayer structure with a cavity therebetween; and measuring a frequency characteristics between the first and second lead electrodes and if the measured frequency is low or high, forming an etched part of a first protective film provided below the multilayer structure or of a second protective film on the multilayer structure, or a deposited layer part on a first protective film provided below the multilayer structure or on a second protective film on the multilayer structure, opposite the fine holes.

### BRIEF DESCRIPTION OF THE DRAWINGS

FIG. 1 is a schematic cross-section component diagram of a thin film piezoelectric resonator according to the first embodiment of the present invention.

FIG. 2 is a schematic cross-section component diagram describing one step of a manufacturing method for a thin film piezoelectric resonator according to the first embodiment of the present invention.

FIG. 3 is a schematic cross-section component diagram describing one step of a manufacturing method for a thin film piezoelectric resonator according to the first embodiment of the present invention.

FIG. 4 is a schematic cross-section component diagram describing one step of a manufacturing method for a thin film piezoelectric resonator according to the first embodiment of the present invention.

FIG. 5 is a schematic cross-section component diagram describing one step of a manufacturing method for a thin film piezoelectric resonator according to the first embodiment of the present invention.

FIG. 6 is a schematic cross-section component diagram describing one step of a manufacturing method for a thin film piezoelectric resonator according to the first embodiment of the present invention.

FIG. 7 is a schematic cross-section component diagram describing one step of a manufacturing method for a thin film piezoelectric resonator according to the first embodiment of the present invention.

FIG. 8 is a schematic cross-section component diagram describing one step of a manufacturing method for a thin film piezoelectric resonator according to the first embodiment of the present invention.

FIG. 9 is a schematic cross-section component diagram describing one step of a manufacturing method for a thin film piezoelectric resonator according to the first embodiment of the present invention.

FIG. 10 is a schematic cross-section component diagram describing one step of a manufacturing method for a thin film piezoelectric resonator according to the first embodiment of the present invention.

FIG. 11 is a schematic cross-section component diagram describing one step of a manufacturing method for a thin film piezoelectric resonator according to the first embodiment of the present invention.

FIG. 12 is a schematic cross-section component diagram describing one step of an alternate example of a manufacturing method for a thin film piezoelectric resonator according to the first embodiment of the present invention.

FIG. 13 is a schematic cross-section component diagram describing one step of an alternate example of a manufacturing method for a thin film piezoelectric resonator according to the first embodiment of the present invention.

FIG. 14 is a schematic cross-section component diagram of a thin film piezoelectric resonator for resonance frequency downward trimming performed for a thin film piezoelectric resonator according to the first embodiment of the present invention.

FIG. 15 is a schematic cross-section component diagram describing a sputtering method for resonance frequency downward trimming applied to a manufacturing process for a thin film piezoelectric resonator according to the first embodiment of the present invention.

FIG. 16 is a schematic cross-section component diagram of a thin film piezoelectric resonator for resonance frequency upward trimming performed for a thin film piezoelectric resonator according to the first embodiment of the present invention.

FIG. 17 is a schematic cross-section component diagram describing an argon ion beam etching method for resonance frequency upward trimming applied to a manufacturing process for a thin film piezoelectric resonator according to the first embodiment of the present invention.

FIG. 18 is a schematic cross-section component diagram describing an argon plasma etching method for resonance frequency upward trimming applied to a manufacturing process for a thin film piezoelectric resonator according to the first embodiment of the present invention.

FIG. 19 is a schematic cross-section component diagram describing an oblique direction sputtering method for bonding to a sealing material applied in a manufacturing process for a thin film piezoelectric resonator according to the first embodiment of the present invention.

FIG. 20 is a schematic cross-section component diagram describing an oblique direction argon ion beam etching method for bonding to a sealing material applied in a manufacturing process for a thin film piezoelectric resonator according to the first embodiment of the present invention.

FIG. 21 is a schematic cross-section component diagram of a thin film piezoelectric resonator according to the second embodiment of the present invention.

FIG. 22 is a schematic cross-section component diagram describing one step of a manufacturing method for a thin film piezoelectric resonator according to the second embodiment of the present invention.

FIG. 23 is a schematic top view pattern component diagram describing one step of a manufacturing method for a thin film piezoelectric resonator according to the second embodiment of the present invention.

FIG. 24 is a schematic cross-section component diagram describing one step of a manufacturing method for a thin film piezoelectric resonator according to the second embodiment of the present invention.

FIG. 25 is a schematic cross-section component diagram describing one step of a manufacturing method for a thin film piezoelectric resonator according to the second embodiment of the present invention.

FIG. 26 is a schematic cross-section component diagram describing one step of a manufacturing method for a thin film piezoelectric resonator according to the second embodiment of the present invention.

FIG. 27 is a schematic cross-section component diagram describing one step of a manufacturing method for a thin film piezoelectric resonator according to the second embodiment of the present invention.

FIG. 28 is a schematic cross-section component diagram describing one step of a manufacturing method for a thin film piezoelectric resonator according to the second embodiment of the present invention.

FIG. 29 is a schematic cross-section component diagram describing one step of a manufacturing method for a thin film piezoelectric resonator according to the second embodiment of the present invention.

FIG. 30 is a schematic cross-section component diagram describing one step of a manufacturing method for a thin film piezoelectric resonator according to the second embodiment of the present invention.

FIG. 31 is a schematic cross-section component diagram describing one step of a manufacturing method for a thin film piezoelectric resonator according to the second embodiment of the present invention.

FIG. 32 is a schematic cross-section component diagram describing one step of a manufacturing method for a thin film piezoelectric resonator according to the third embodiment of the present invention.

FIG. 33 is a schematic cross-section component diagram describing one step of a manufacturing method for a thin film piezoelectric resonator according to the third embodiment of the present invention.

FIG. 34 is a schematic cross-section component diagram describing one step of a manufacturing method for a thin film piezoelectric resonator according to the third embodiment of the present invention.

FIG. 35 is a schematic cross-section component diagram describing one step of a manufacturing method for a thin film piezoelectric resonator according to the third embodiment of the present invention.

FIG. 36 is a schematic cross-section component diagram describing one step of a manufacturing method for a thin film piezoelectric resonator according to the third embodiment of the present invention.

FIG. 37 is a schematic cross-section component diagram describing one step of a manufacturing method for a thin film piezoelectric resonator according to the third embodiment of the present invention.

FIG. 38 is a schematic cross-section component diagram describing one step of a manufacturing method for a thin film piezoelectric resonator according to the third embodiment of the present invention.

FIG. 39 is a schematic cross-section component diagram describing one step of a manufacturing method for a thin film piezoelectric resonator according to the third embodiment of the present invention.

FIG. 40 is a schematic cross-section component diagram describing one step of a manufacturing method for a thin film piezoelectric resonator according to the fourth embodiment of the present invention.

FIG. 41 is a schematic cross-section component diagram describing one step of a manufacturing method for a thin film piezoelectric resonator according to the fourth embodiment of the present invention.

FIG. 42 is a schematic cross-section component diagram describing one step of a manufacturing method for a thin film piezoelectric resonator according to the fourth embodiment of the present invention.

FIG. 43 is a schematic cross-section component diagram describing one step of a manufacturing method for a thin film piezoelectric resonator according to the fourth embodiment of the present invention.

FIG. 44 is a schematic top view diagram describing one step of a manufacturing method for a thin film piezoelectric resonator according to the fourth embodiment of the present invention.

FIG. 45 is a schematic cross-section component diagram describing one step of a manufacturing method for a thin film piezoelectric resonator according to the fourth embodiment of the present invention.

FIG. 46 is a schematic cross-section component diagram describing one step of a manufacturing method for a thin film piezoelectric resonator according to the fourth embodiment of the present invention.

FIG. 47 is a schematic cross-section component diagram describing one step of a manufacturing method for a thin film piezoelectric resonator according to the fourth embodiment of the present invention.

FIG. 48 is a schematic cross-section component diagram describing a thin film piezoelectric resonator according to the fourth embodiment of the present invention.

FIG. 49 is a schematic diagram showing the frequency characteristics of a thin film piezoelectric resonator according to an embodiment of the present invention.

FIG. 50 is a schematic diagram showing the frequency characteristics of a bandpass filter obtained by combining a plurality of thin film piezoelectric resonators according to an embodiment of the present invention.

FIG. 51 is a schematic component diagram of a bandpass filter circuit that uses thin film piezoelectric resonators according to an embodiment of the present invention.

FIG. 52 is a top view pattern component diagram of FIG. 51.

FIG. 53 is a schematic diagram of a mobile phone that uses a circuit block construction schematically shown in FIG. 54.

FIG. 54 is a schematic block component diagram showing an application example of the bandpass filter shown in FIG. 51 of a bandpass filter circuit that uses thin film piezoelectric resonators according to an embodiment of the present invention.

### DETAILED DESCRIPTION

Next, the first through fourth embodiments of the present invention will be described while referring to the drawings. In the following drawings, identical or similar components have been assigned the same or similar reference numerals. However, the drawings are schematic drawings and one must realize that the relationship between the thickness and area dimensions and the ratios of the thicknesses of the layers differ from the actual condition. Therefore, specific thicknesses and dimensions should be determined by referring to the following description. Furthermore, some of the relationships and ratios are of course different between the dimensions in different drawings.

Furthermore, the following first through fourth embodiments are examples showing the devices and methods for visualizing the technical concepts of the present invention, and these technical concepts of the invention are not specific to the materials, shapes, construction, or arrangement or the like of the components shown below. The technical concepts of the present invention can include various changes within the scope of the patent claims.

With the thin film piezoelectric resonator according to an embodiment of the present invention as well as the manufacturing method thereof, when a cavity is formed in the thin film piezoelectric resonator, a plurality of fine holes are formed directly above or in the region directly above the resonator of a layer which forms a cover over a sacrificial layer that is later removed. Afterwards, the sacrificial layer is selectively removed. Furthermore, the frequency is adjusted either upwards or downwards by physically etching or physically depositing through the fine holes, and lastly these fine holes are sealed.

With the thin film piezoelectric resonator according to an embodiment of the present invention as well as a manufacturing method thereof, fine holes with a high aspect ratio are used to make fine adjustments to the resonance frequency. By etching or depositing through fine holes with a high aspect ratio, the control properties can be increased by suppressing the etching or deposition rate to less than a fraction of the rate when etching or deposition is not performed through the fine holes. Furthermore, the fine holes are formed either directly above or directly below the thin film piezoelectric resonator, so the sacrificial layer can be effectively removed by isotropic etching. Finally, the cavity must be sealed with good hermeticity. For the case where a binder such as solder is used on the opposing substrate side, if a large hole is opened and the construction supports the perimeter thereof, penetration by the binder can severely interfere with the resonator, but with the thin film piezoelectric resonator of an embodiment of the present invention as well as the manufacturing method thereof, this phenomenon is suppressed, and sealing with good hermeticity can be achieved. In other words, there is a possibility that binder such as solder or the like can contact with the resonator if there is a large opening, but with the thin film piezoelectric resonator according to an embodiment of the present invention as well as the manufacturing method thereof, an embedded insulating layer with fine holes is used so penetration by a binder such as solder or the like can be suppressed.

### Embodiment 1

### Element Construction

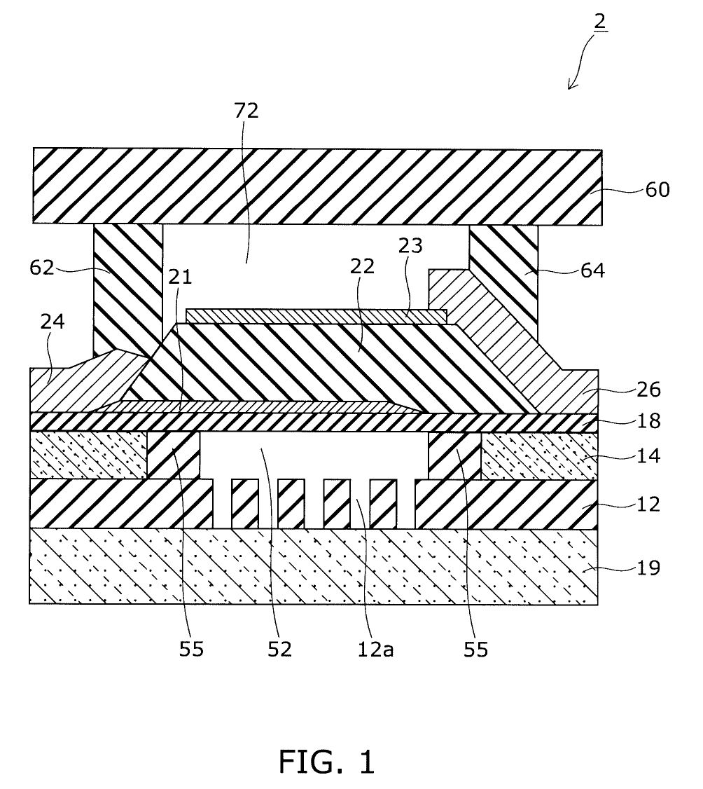

As shown in FIG. 1, the thin film piezoelectric resonator 2 according to the first embodiment of the present invention comprises an embedded insulating layer 12 with fine holes 12a positioned on a sealing member 19, a semiconductor layer 14 with a cavity 52 above the fine holes 12a positioned above the embedded insulating layer 12, a protective film 18 positioned on the semiconductor layer 14 and the cavity 52, a lower electrode 21 located on the protective layer 18, a piezoelectric film 22 located on the lower electrode 21, an upper electrode 23 located on the piezoelectric film 22, a first lead electrode 24 connected to the lower electrode 21 and located on the protective film 18, and a second lead electrode 26 that is connected to the upper electrode 23 and is positioned on the protective film 18.

Furthermore, as shown in FIG. 1, a hollow designated region 55 consisting of a protective insulating film of the same material as the embedded insulating layer 12 can also be formed in the side wall of the cavity 52 in the semiconductor layer 14.

Furthermore, as shown in FIG. 1, the first lead electrode 24 and the second lead electrode 26 have supporting parts 62, 64 located in a manner which forms a cavity 72 on the upper electrode 23 and protects the multilayer construction of the thin film piezoelectric resonator which is consisting of the lower electrode 21, piezoelectric film 22, and the upper electrode 23, and also have a sealing member 60 located on the supporting parts 62, 64 which seals the cavity 72.

As shown in FIG. 1, a sealing member 19 made from a semiconductor material is positioned to be attached to the embedded insulating layer 12 from the back side in order to seal the fine holes 12a with good hermeticity.

The cavity 52 is formed by etching the semiconductor layer 14 through the fine holes 12a.

Resonance frequency upward trimming is performed by etching the protective layer 18 through the fine holes 12a, or resonance frequency downward trimming is performed by forming a deposition metal layer on the protective film 18 through the fine holes 12a. In other words, the frequency characteristics between the first and the second lead electrodes are measured, and if the measurement value is low or is high, an etching region or a deposition layer is formed on the protective film 18 opposite to the fine holes 12a. In FIG. 1, the etching region or the deposition film region of the protective film 18 that is formed opposite to the fine holes 12a is not shown in the drawing. Note, this type of high-frequency trimming is appropriately performed based on the measurement results of the resonance frequencies, and frequency trimming is obviously not required if the resonance frequencies match.

From the viewpoint of protecting the resonator part during etching, the protective layer 18 is a substance with high chemical resistance such as aluminum nitride (A1N) or the like. The support parts 62, 64 and the sealing member 60 can be made of a heat resistant polymer such as polyimide or the like.

The piezoelectric film 22 of the resonator part of the thin film piezoelectric resonator 2 will be energized and resonate by bulk acoustic waves because of the high-frequency signal applied between the lower electrode 21 and the upper electrode 23. For example, a high-frequency signal in the gigahertz range is applied between the lower electrode 21 and the upper electrode 23, causing the piezoelectric film 22 of the resonator unit of the thin film piezoelectric resonator to resonate. In order to achieve good resonating characteristics in the resonator unit, an AIN film or a ZnO film with excellent film thickness uniformity and film properties including crystal orientation and the like is used as the piezoelectric film 22. The lower electrode 21 can be a multilayer metal film such as aluminum (Al) or tantalum aluminum (TaAl) or the like, or a high melting point metal such as molybdenum (Mo), tungsten (W), or titanium (Ti) or the like or a metal compound containing a high melting point metal.

The upper electrode 23 can be a metal compound that contains a metal such as Al, a high melting point metal such as Mo, W, or Ti, or a metal compound that contains a high melting point metal.

As shown in FIG. 1, the thin film piezoelectric resonator 2 of the first embodiment of the present invention has a construction where lead electrodes 24, 26 are retracted from the direction of the top side of the protective film 18 that constitutes a multilayer structure of the thin film piezoelectric resonator 2, and fine holes 12a for adjusting the resonance frequency are arranged in the lower direction of the multilayer structure of the thin film piezoelectric resonator 2, and therefore a weight for adjusting the mass can be deposited and formed on the protective film 18 through the fine holes 12a from the bottom direction of the multilayer construction of the thin film piezoelectric resonator 2 in order to perform resonance frequency downward trimming, or argon plasma processing or ion beam etching can be performed on the protective film 18 through the fine holes 12a from the bottom direction of the multilayer structure of the thin film piezoelectric resonator 2 in order to make the film more fine and thin in order to perform resonance frequency upward trimming.

Alternatively, with the thin film piezoelectric resonator 2 of the first embodiment of the present invention, instead of forming a metal deposition film such as Au—Sn or the like in order to adjust the mass, an insulating layer for adjusting the mass can be deposited on the protective film 18 through the fine holes 12a using a method such as bias sputtering, for example, from the bottom direction of the multilayer structure of the thin film piezoelectric resonator 2, and thereby perform frequency downward trimming.

### Manufacturing Method

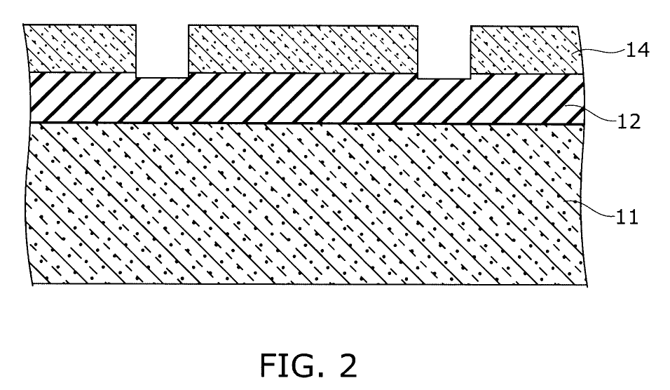

FIG. 2 through FIG. 15 schematically show the cross-section structure for explaining one step of the manufacturing method of the thin film piezoelectric resonator according to the first embodiment of the present invention. The manufacturing method for the thin film piezoelectric resonator according to the first embodiment of the present invention will be described while referring to FIG. 2 through FIG. 15.

(A) First, as shown in FIG. 2, an embedded insulating layer 12 is formed on a semiconductor substrate 11, a semiconductor layer 14 is formed on the embedded insulating layer 12, and then grooves are formed in the semiconductor layer 14 with a depth that extends to the embedded insulating layer 12.

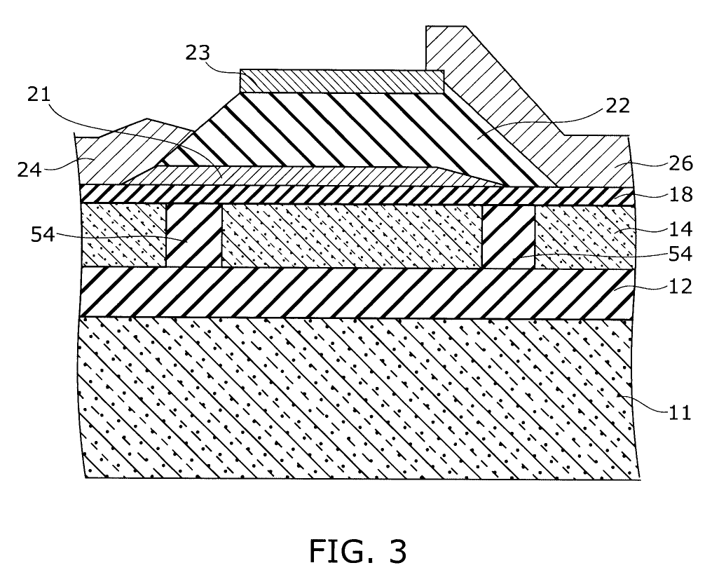

As shown in FIG. 3, these grooves are filled by a protective insulating film, and demarcate the semiconductor layer 14 on the lower region where the resonator unit will be formed, as a hollow designated region 55. Furthermore, as will be described later, these grooves separate each of the elements in the case where a plurality of thin film piezoelectric resonators are formed by deposition.

The SOI substrate shown in FIG. 2 can for instance be formed by ion injection of oxygen or nitrogen or the like into the semiconductor substrate 11 using SIMOX technology or the like.

Alternatively, the semiconductor layer 14 can be formed by depositing polycrystals using crystal growth on the embedded insulating layer 12, and then monocrystalizing the polycrystals using laser annealing technology.

Alternatively, the semiconductor layer 14 can be formed by overlaying an oxidized wafer using overlaying technology, and then polishing using polishing technology.

In order to prevent leaking of radiofrequencies, the semiconductor layer 14 is preferably a high resistance semiconductor layer with a resistivity of 1000 ohms cm or higher.

(B) Next, as shown in FIG. 3, the grooves are filled with an insulating film such as a TEOS (tetraethoxysilane) film or the like to form a hollow designated region 55, smoothing is performed using chemical-mechanical polishing (CMP), a protective film 18 is deposited, and then a lower electrode 21, piezoelectric film 22, and upper electrode 23 are formed in succession on the protective film 18 in order to form the multilayer structure of the thin film piezoelectric resonator. Furthermore, a lead electrode 24 is formed for the lower electrode 21 and a lead electrode 26 is formed for the upper electrode 23.

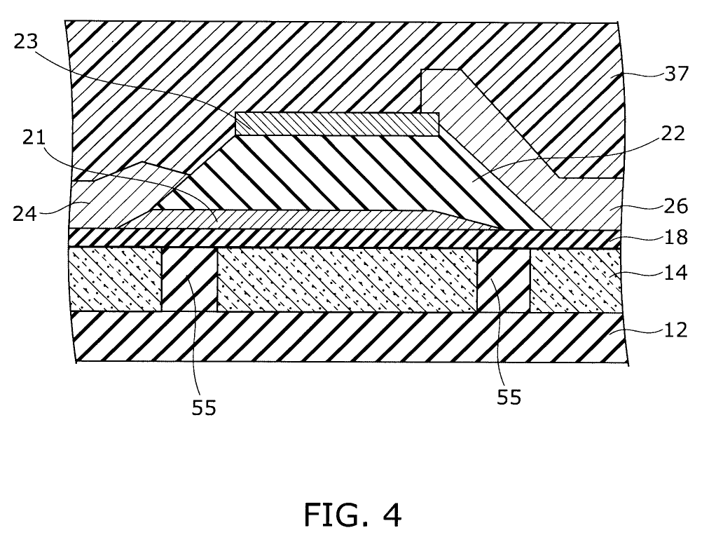

(C) Next, as shown in FIG. 4, a protective resist layer 37 is deposited on the lead electrode 24, piezoelectric film 22, upper electrode 23, and lead electrode 26, in order to protect the surface.

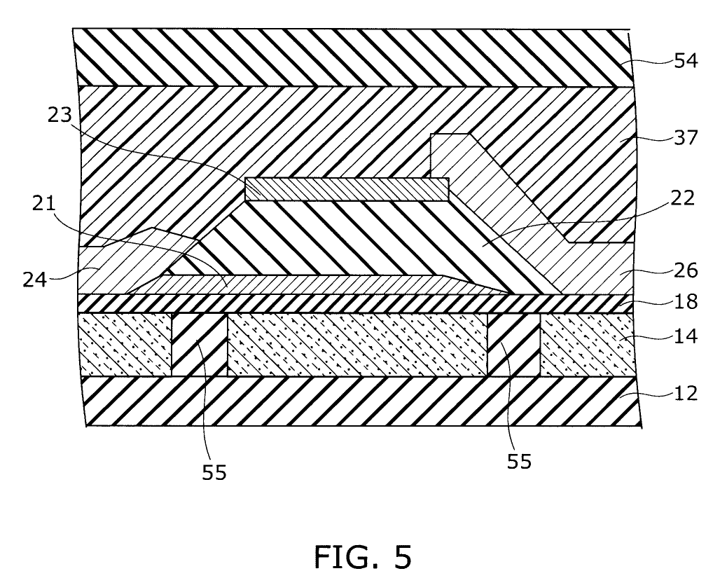

(D) Next, as shown in FIG. 5, a foam tape 54 for instance is applied as a reinforcing member over the protective resist layer 37. Furthermore, film thinning etching is performed on the semiconductor substrate 11 on the back surface until the back surface of the embedded insulating layer 12 is exposed. For example, wafer thinning is performed to a level of several tens of micrometers or less.

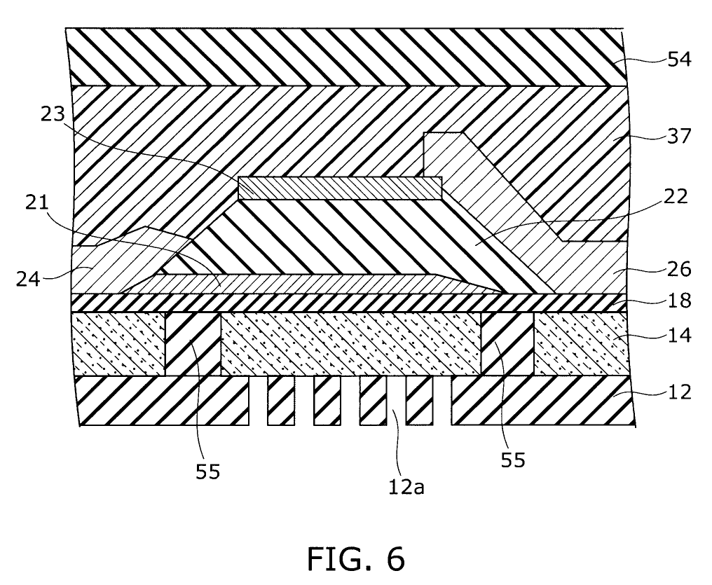

(E) Next, as shown in FIG. 6, fine holes 12a are formed in the embedded insulating layer 12 extending to the semiconductor layer 14 using lithography technology and reactive ion etching (RIE) technology. A plurality of fine holes 12a can be formed. Furthermore, as shown in FIG. 6, the position for forming these fine holes 12a is at the bottom of the semiconductor layer 14 that contacts with the protective layer 18, and the protective layer 18 that contacts the lower electrode 21. In other words, a plurality of fine holes 12a may be formed in the region directly below the resonator unit. Furthermore, marks for lithography can be formed when embedding the insulating film and forming the aforementioned grooves.

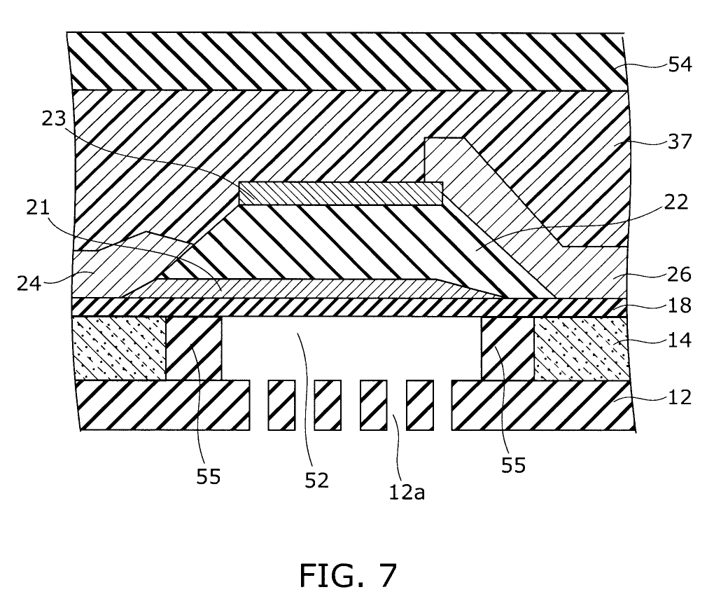

(F) Next, as shown in FIG. 7, the semiconductor layer 14 is selectively removed through the fine holes 12a using isotropic etching technology such as a wet etching technology or the like, in order to form a cavity 52.

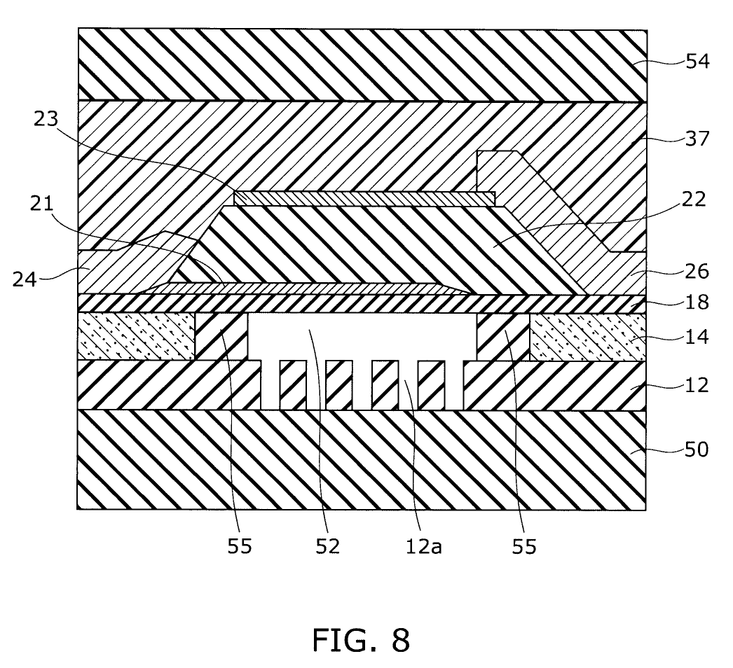

(G) Next, as shown in FIG. 8, a reinforced tape 50 is applied to the embedded insulating layer 12 on the backside using a temporary adhesive to prevent adhesive from remaining after peeling for example.

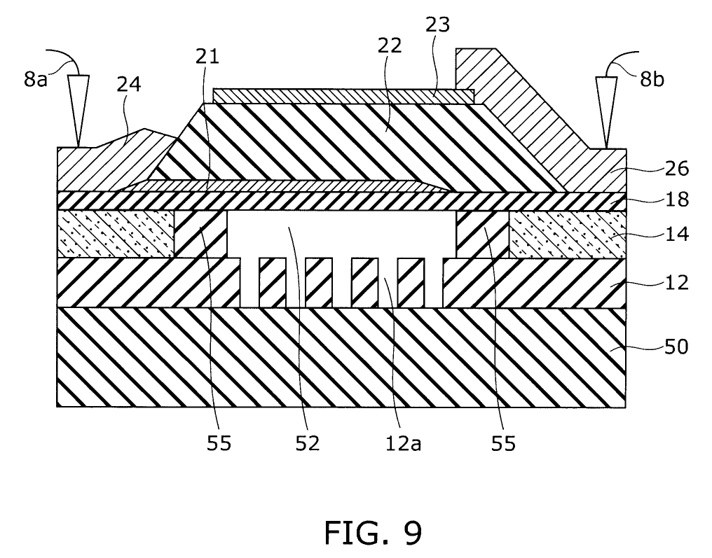

(H) Next, as shown in FIG. 9, the foam tape 54 on the front side is removed, and then the protective resist layer 37 is removed, needles for probes 8a and 8b are applied to the lead electrodes 24 and 26, and the electrical characteristics and frequency characteristics or the like of the thin film piezoelectric resonator are measured. The characteristics are detected to determine whether the values are higher, lower, or equal to the target resonance frequency.

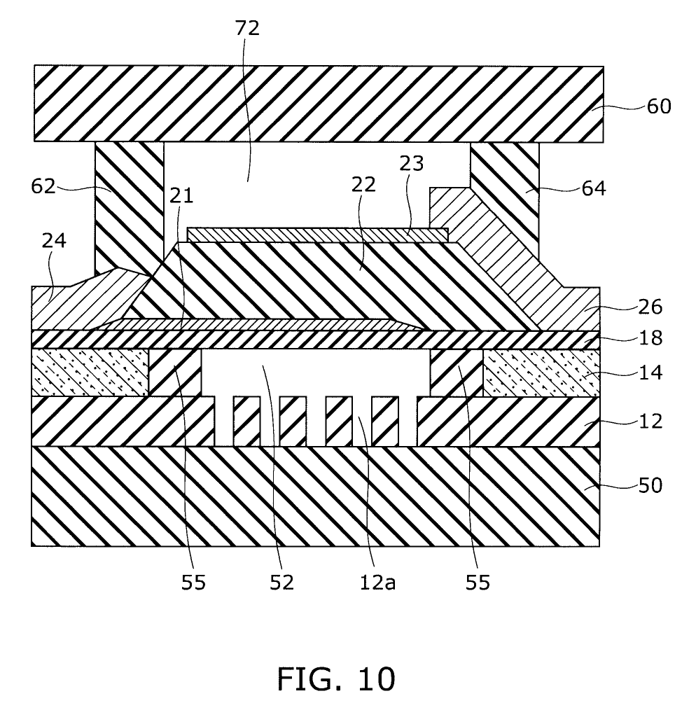

(I) Next, as shown in FIG. 10, sealing of the hollow region on the front surface side is completed on the wafer level by the supporting parts 62, 64, and the sealing member 60 in order to form a cavity 72. The cavity 72 can for instance be filled with nitrogen or argon or the like. The support parts 62, 64 can be formed from polyimide or the like.

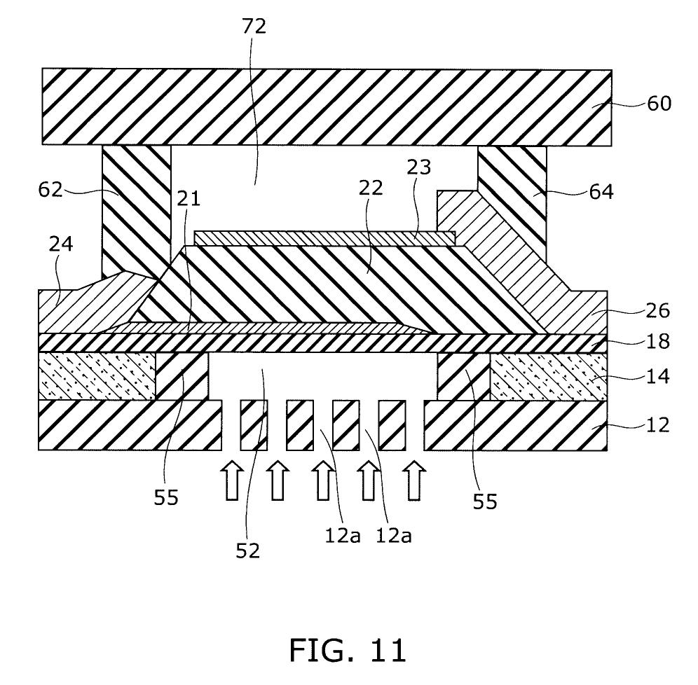

(J) Next, as shown in FIG. 11, the reinforced tape 50 is removed from the back surface, and then the frequency is adjusted by appropriately performing physical etching or physical deposition through the fine holes 12a formed in the back surface.

Because etching or depositing is performed through the fine hole 12a, the etching or depositing rate can be suppressed to a fraction of the rate when performed directly without passing through the fine holes 12a, and therefore fine adjusting is possible.

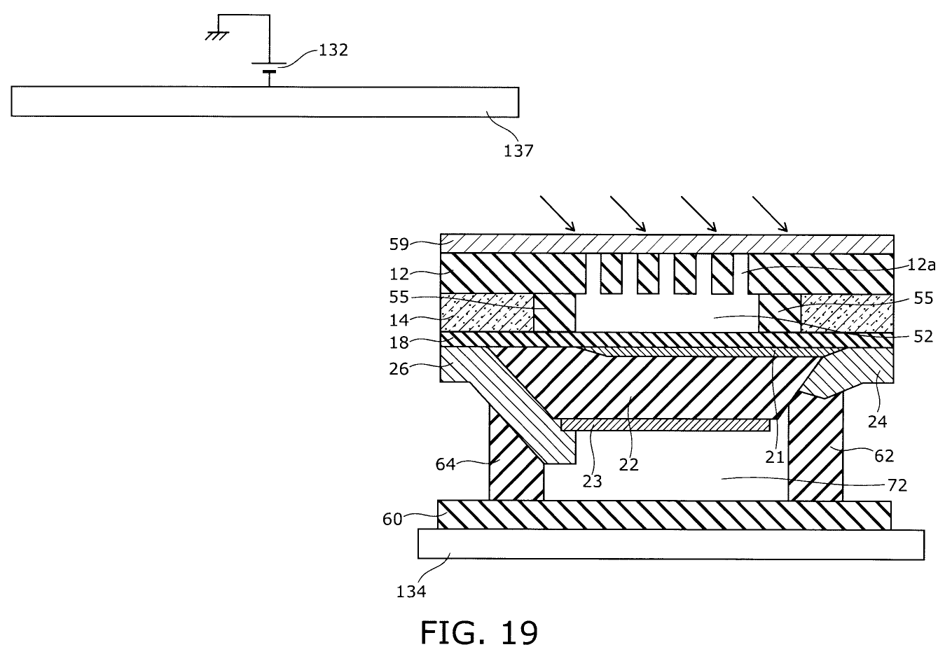

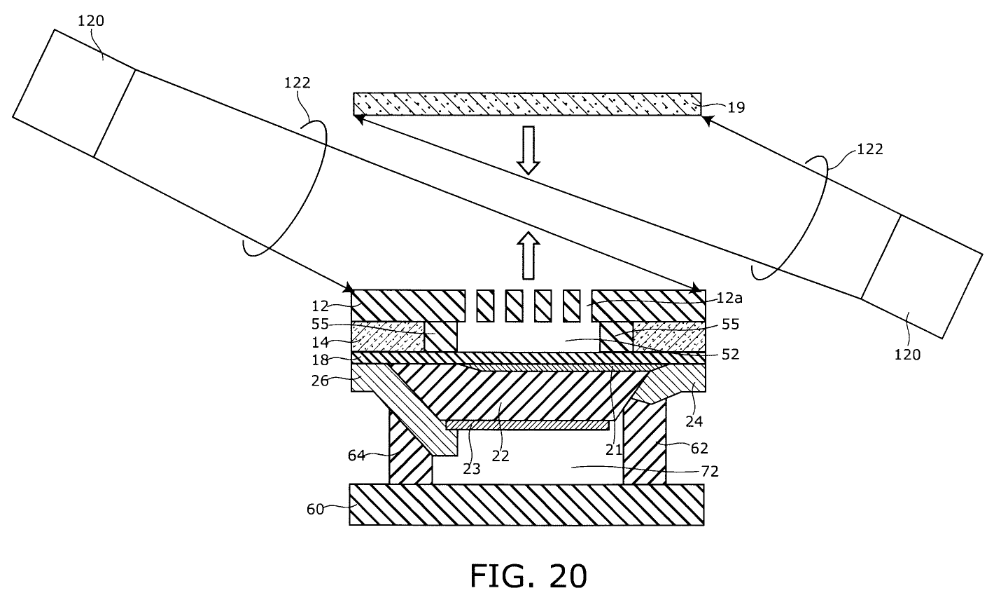

(K) Next, after dicing, sealing the hollow region on the back surface is completed by directly applying a sealing member 19 made from a semiconductor for instance to the back surface side using bonding technology that uses a glass frit, metal bonding technology as shown in FIG. 19, or ambient temperature bonding technology as shown in FIG. 20, and thereby forming the cavity 52. The cavity 52 can for instance be filled with nitrogen or argon or the like.

### Alternate Example of Manufacturing Method

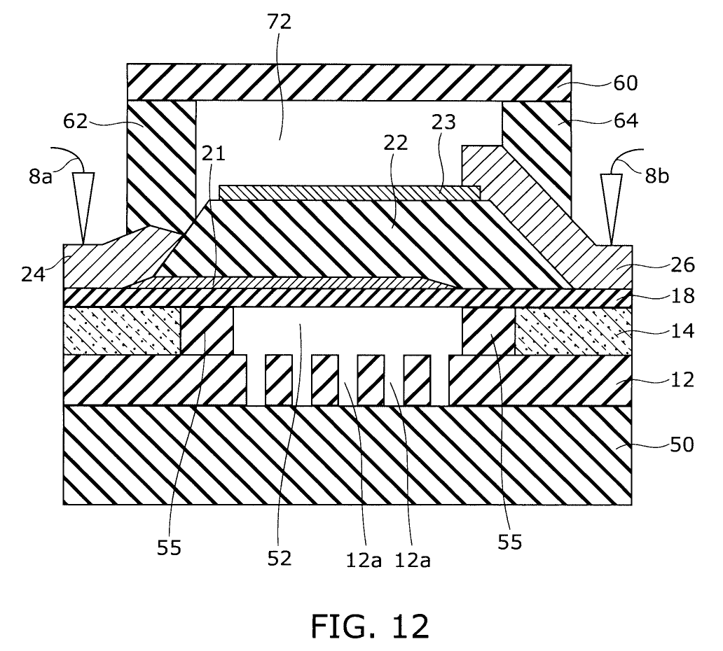

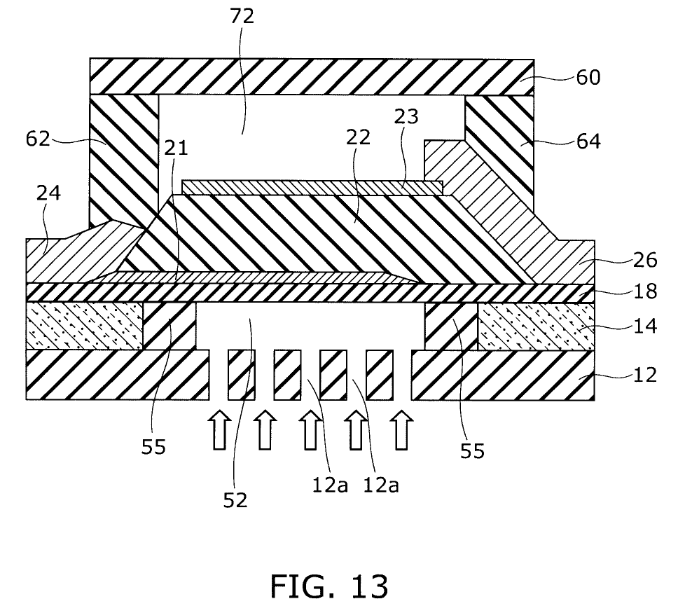

FIG. 12 through FIG. 13 schematically show the cross-section structure for explaining one step of an alternate example of the manufacturing method of the thin film piezoelectric resonator according to the first embodiment of the present invention. An alternate example of the manufacturing method for the thin film piezoelectric resonator according to the first embodiment of the present invention will be described while referring to FIG. 12 through FIG. 13. The steps shown in FIG. 2 through FIG. 8 are common with the manufacturing method for the thin film piezoelectric resonator according to the first embodiment of the present invention.

(L) As shown in FIG. 8, after the reinforced tape 50 is applied to the embedded insulating layer 12 on the back surface using a temporary adhesive in order to prevent adhesive from remaining after peeling for example, the foam tape 54 is removed from the front side as shown in FIG. 12, and then the protective resist layer 37 is removed.

(M) Next, as shown in FIG. 12, sealing of the hollow on the front surface side is completed by the supporting parts 62, 64, and the sealing member 60 in order to form a cavity 72. The cavity 72 can for instance be filled with nitrogen or argon or the like. Herein, processes such as chip mounting, wafer overlaying, and half-dicing can be combined with the front side sealing process.

(N) Next, as shown in FIG. 12, the needles of probes 8a and 8b are applied to the lead electrodes 24 and 26 in order to measure the electrical characteristics and frequency characteristics of the thin film piezoelectric resonator. The characteristics are detected to determine whether the values are higher, lower, or equal to the target resonance frequency.

(O) Next, as shown in FIG. 13, the reinforced tape 50 is removed from the back surface, and then the resonance frequency is adjusted by appropriately performing physical etching or physical deposition through the fine holes 12a formed in the back surface. Because etching or depositing is performed through the fine holes 12a, the etching or deposition rate can be suppressed to a fraction of the rate when performed directly without passing through the fine holes 12a, and therefore fine adjusting is possible.

(P) Next, after dicing, sealing the hollow on the back surface is completed by directly applying a sealing member 19 made from a semiconductor for instance to the back surface side using bonding technology that uses a glass frit, metal bonding technology as shown in FIG. 19, or ambient temperature bonding technology as shown in FIG. 20, and thereby forming the cavity 52. The cavity 52 can for instance be filled with nitrogen or argon or the like.

### Resonance Frequency Downward Trimming

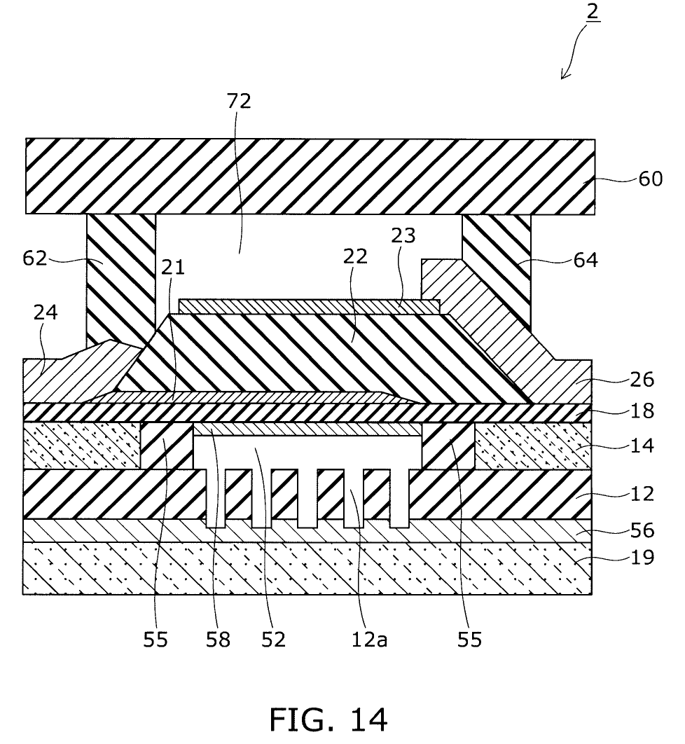

With the manufacturing method for the thin film piezoelectric resonator according to the first embodiment of the present invention, as shown in FIG. 14, the resonance frequency downward trimming process can be performed by forming a metal deposition layer 58 on the protective layer 18 in the cavity 52 through the fine holes 12a from the bottom direction of the multilayer construction of the thin film piezoelectric resonator 2.

As a process of depositing weight for adjusting the mass on the protective film 18, a metal such as Au—Sn or the like can be deposited on the protective film 18 through the fine holes 12a. In the process of depositing a metal such as Au—Sn , the back surface of the embedded insulating layer 12 in which the fine holes 12a are formed can be simultaneously coated as shown in FIG. 14, and a metal deposition layer 56 will be formed, so using the metal deposition layer 56 as a favorable adhesive layer for the subsequent sealing member 19 is effective. In this case, the connection with the adjacent sealing member 19 which is made from a semiconductor material can easily be achieved by forming a metal layer on the front side of the sealing member 19 and therefore forming a metal deposition layer 56 and an ambient temperature bond will be simple. The shape of the metal deposition layer 56 shown in FIG. 14 is the shape where the metal deposition film deposited on the embedded insulating layer 12 is joined with the metal layer formed on the sealing member 19.

As shown in FIG. 14, the metal deposition layer 58 formed by depositing a metal such as Au—Sn through the fine holes 12a on the protective layer 18 is formed as a flat layer, but depositing in other shapes is possible depending on the width and depth of the fine holes 12a and the conditions for forming the deposition layer. For example, if the width of the fine holes 12a is narrow and the depth is deep, the film will be thick directly above the fine holes 12a and will be thin in the surrounding regions, and therefore a wavy shape will be formed. Alternatively, a dotted shape or a striped shape can be formed reflecting the pattern of the fine holes 12a directly above the fine holes 12a.

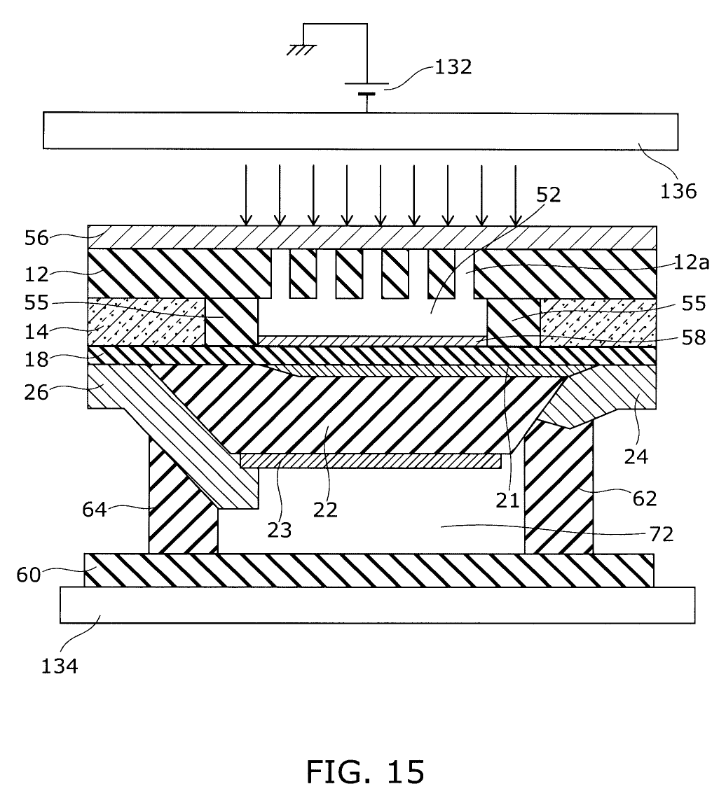

The method for depositing metal such as Au—Sn or the like on the protective film 18 through the fine holes 12a is shown for example in FIG. 15. In other words, the thin film piezoelectric resonator structure shown in FIG. 11 or FIG. 13 is placed on a sample holder 134, and a metal deposition film 56, 58 is formed on the deposition target 136 by a direct current bias sputtering method in an argon (Ar) environment at approximately 0.1 to several Pa. Au—Sn may be used for example as the target material.

A negative direct current bias voltage of several hundred volts is applied to the deposition target 136 by a direct current power source 132.

### Resonance Frequency Upward Trimming

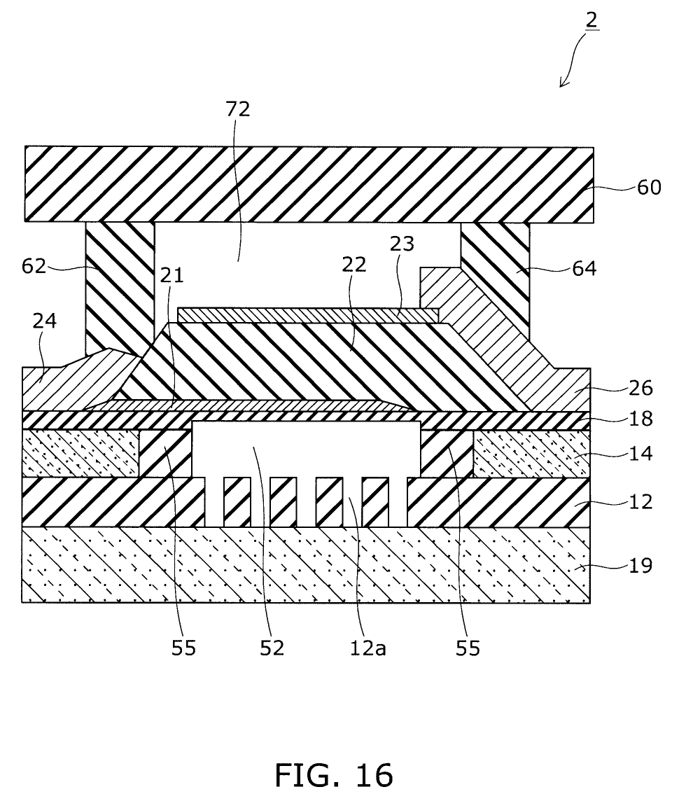

With the manufacturing method for the thin film piezoelectric resonator according to the first embodiment of the present invention, as shown in FIG. 16, the resonance frequency upward trimming process can be performed by etching the protective layer 18 in the cavity 52 through the fine holes 12a from the bottom direction of the multilayer construction of the thin film piezoelectric resonator 2. As a result, as shown in FIG. 16, the protective layer 18 at the bottom of the multilayer structure of the thin film piezoelectric resonator 2 is made thinner, and protective film 18a is formed. Herein, the shape of the protective film 18a shown in FIG. 16 is a flat layer, but this shape can also be rippled or have protrusions and recesses rather than being flat, reflecting the pattern of the fine holes 12a which are formed in the embedded insulation layer 12.

If the argon plasma processing or ion beam etching is performed on the protective film 18 through the fine holes 12a from the bottom of the multilayer structure of the thin film piezoelectric resonator 2, the argon plasma processing or the ion beam etching will also be performed simultaneously on the back surface of the embedded insulating layer 12 into which the fine holes 12a are formed, so there is an advantage that ambient temperature bonds can easily be formed with the embedded insulating layer 12 because the bonding surface of the adjacent sealing member 19 which is made from a semiconductor will be made smooth by the argon plasma processing or the ion beam etching.

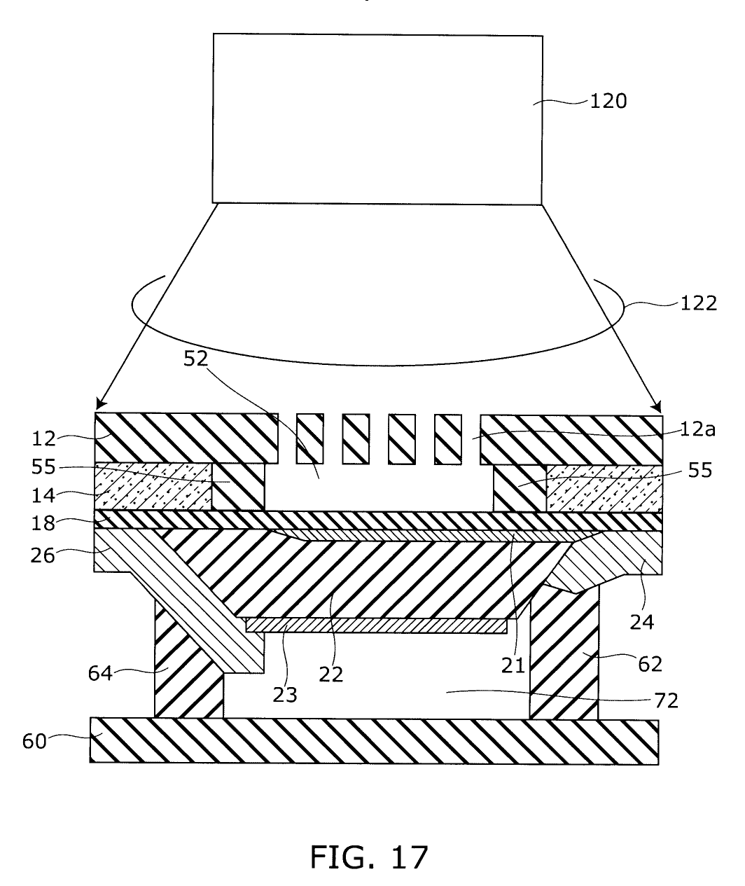

A method of performing ion beam etching on the protective film 18 through the fine holes 12a from the bottom of the multilayer structure of the thin film piezoelectric resonator 2 is shown for example in FIG. 17. In other words, the construction of the thin film piezoelectric resonator shown in either FIG. 11 or FIG. 13 is placed in an ion beam etching device, and an ion beam 122 from an argon (Ar) ion beam source 120 is irradiated onto the embedded insulating layer 12 into which the fine holes 12a are formed, and ion beam etching of the protective layer 18 can be performed with high precision by the ion beam 122 which passes through the fine holes 12a. Furthermore, the surface of the embedded insulating layer 12 into which the fine holes 12a are formed is also ion beam etched, and therefore the adjacent sealing member 19 made from a semiconductor can be bonded by using this activated surface as is.

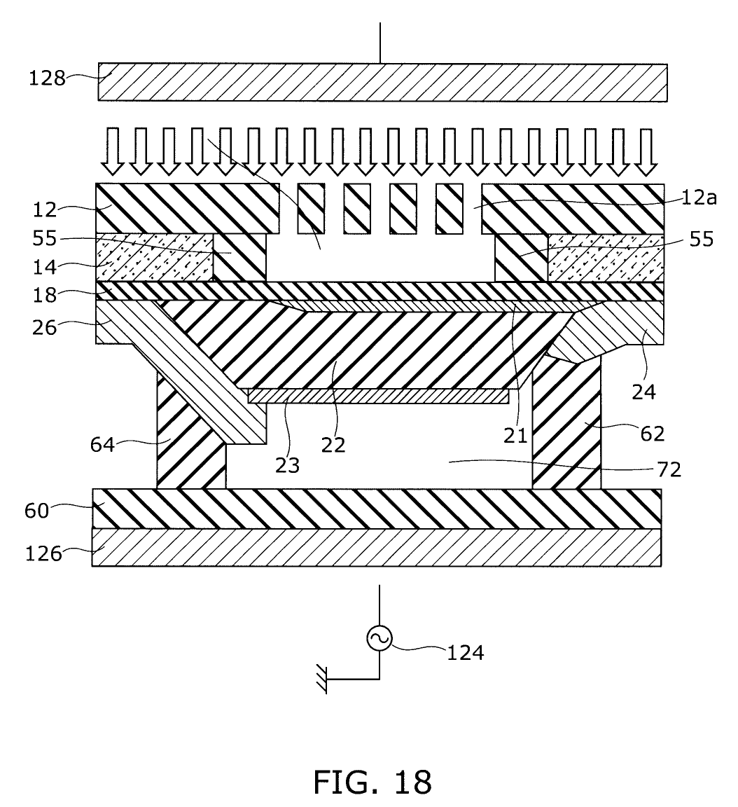

A method of performing argon plasma etching on the protective film 18 through the fine holes 12a from the bottom of the multilayer structure of the thin film piezoelectric resonator 2 is shown for example in FIG. 18. In other words, the construction of the thin film piezoelectric resonator shown in either FIG. 11 or FIG. 13 is placed on an electrode 126 that is connected to a high-frequency power source 124 that has a frequency of 13.56 MHz, and then plasma etching in an argon (Ar) environment at a pressure between approximately 0.1 and several Pa is performed in the area between the opposing electrode 128, and therefore plasma etching of the protective film 18 can be performed with good precision by the portion of the argon plasma which passes through the fine holes 12a. Furthermore, the surface of the embedded insulating layer 12 into which the fine holes 12a are formed is also plasma etched, and therefore the adjacent sealing member 19 made from a semiconductor can be bonded by using this activated surface as is. By applying a direct current bias voltage of several hundred volts to the opposing electrode 128, the argon plasma ions which are generated can be effectively introduced to the surface of the embedded insulating layer 12 into which the fine holes 12a are formed, and to the surface of the protective film 18 inside the cavity 52.

### Bonding Method

With the manufacturing method for a thin film piezoelectric resonator according to the first embodiment of the present invention, the method for bonding the embedded insulating layer 12 into which the fine holes 12a are formed to the sealing member 19 made from a semiconductor material can be performed using an off-spackling method as shown in FIG. 19. In other words, as shown in FIG. 19, the thin film piezoelectric resonator structure shown in either FIG. 11 or FIG. 13 is placed on a sample holder 134, and a bonding material deposition layer 59 is formed between the bonding material target 137 to which a direct current bias is applied from a direct current power source 132 using a direct current bias off-spackling method only on the surface of the embedded insulating layer 12 into which the fine holes 12a were formed. Au—Sn may be used for example as the bonding material. A negative direct current bias voltage of several hundred volts is applied to the bonding material target 137. With the off-spackling method shown in FIG. 19, the bonding material can be deposited just on the surface of the embedded insulating layer 12 into which the fine holes 12a were formed, and therefore bonding to the adjacent sealing member 19 made from a semiconductor material can be achieved using the bonding material deposition layer 59.

With the manufacturing method for a thin film piezoelectric resonator according to the first embodiment of the present invention, another method for bonding the embedded insulating layer 12 into which the fine holes 12a are formed to the sealing member 19 made from a semiconductor can be performed using an ion beam etching method as shown in FIG. 20. In other words, as shown in FIG. 20, the construction of the thin film piezoelectric resonator shown in either FIG. 11 or FIG. 13 is placed in an ion beam etching device, and an oblique ion beam 122 from an argon (Ar) ion beam source 120 is irradiated onto the embedded insulating layer 12 into which the fine holes 12a are formed, and ion beam etching can be performed just on the surface of the embedded insulating layer 12 into which the fine holes 12a are formed. In this case, the surface of the embedded insulating layer 12 into which the fine holes 12a were formed will be ion beam etched, so bonding to the adjacent sealing member 19 made of a semiconductor material can be made using the activated surface as is, but as shown in FIG. 20, the oblique ion beam 122 from the argon (Ar) ion beam source 120 will simultaneously be irradiated onto the surface of the sealing member 19, and therefore the embedded insulating layer 12 into which the fine holes 12a are formed and the sealing member 19 can effectively be ambient temperature bonded because the surface of the sealing member 19 has also been activated.

With the thin film piezoelectric resonator according to the first embodiment of the present invention as well as the manufacturing method thereof, resonance frequency upward trimming and resonance frequency downward trimming can be performed with good control by physically etching or physically depositing through the fine holes.

### Embodiment 2

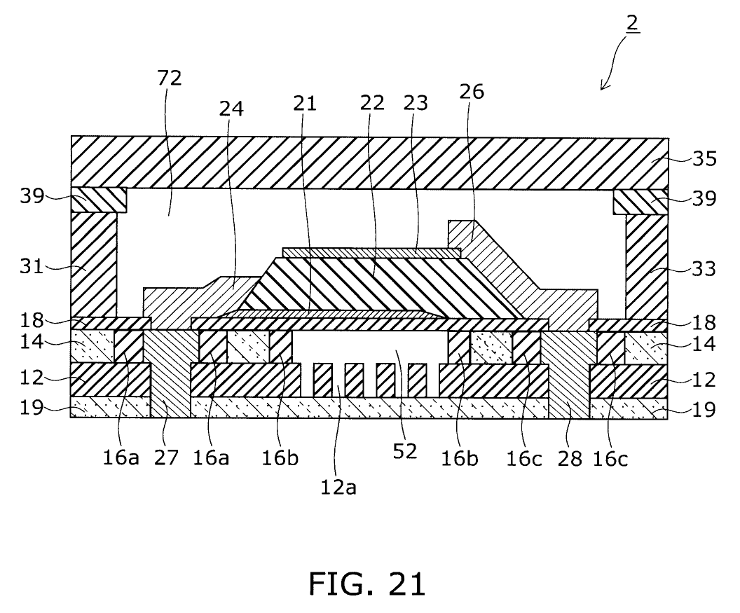

As shown in FIG. 21, the thin film piezoelectric resonator according to the second embodiment of the present invention comprises an embedded insulating layer 12 with fine holes 12a positioned on a sealing member 19, a semiconductor layer 14 with a cavity 52 above the fine holes 12a positioned above the embedded insulating layer 12, a protective film 18 positioned on the semiconductor layer 14 and the cavity 52, a lower electrode 21 located on the protective layer 18, a piezoelectric film 22 located on the lower electrode 21, an upper electrode 23 located on the piezoelectric film 22, a first lead electrode 24 connected to the lower electrode 21 and located on the protective film 18, a second lead electrode 26 that is connected to the upper electrode 23 and is positioned on the protective film 18, a third lead electrode 27 that is connected to the first lead electrode 24 and is located above the protective film 18 on the semiconductor layer 14 side, and a fourth lead electrode 28 connected to the second lead electrode 26 and located above the protective film 18 on the semiconductor layer 14 side.

The cavity 52 is formed by etching the semiconductor layer 14 through the fine holes 12a.

Furthermore, as shown in FIG. 21, a protected insulating film 16b, 16a, 16c with the same material as the embedded insulating layer 12 can be formed on the side wall sections which form the side wall of the cavity 52 in the semiconductor layer 14, as well as on the lead electrodes 27 and 28.

Furthermore, as shown in FIG. 21, supporting parts 31, 33 located in a manner which forms a cavity 72 on the upper electrode 23 and which protects the multilayer construction of the thin film piezoelectric resonator which is consisting of the lower electrode 21, piezoelectric film 22, and the upper electrode 23, and sealing parts 35, 39 located on the supporting parts 31, 33 which seal the cavity 72 are provided on the protective film 18 around the first lead electrode 24 and the second lead electrode 26.

As shown in FIG. 21, a sealing member 19 made from a semiconductor such as silicon (Si) is applied to the back surface of the embedded insulating layer 12 in order to seal the fine holes 12a with good hermeticity.

The protective layer 18 is a substance with high chemical resistance such as aluminum nitride (AlN) from the viewpoint of protecting the lower electrode 21 and the piezoelectric film 22 during etching on the back surface. The support parts 31, 33 and the sealing members 35, 39 can be made of a heat resistant polymer such as polyimide or the like.

In order to achieve good resonating characteristics, an AlN film or a ZnO film with excellent film thickness uniformity and film properties including crystal orientation and the like is used as the piezoelectric film 22. The lower electrode 21 can be a multilayer metal film such as aluminum (Al) or tantalum aluminum (TaAl) or the like, or a high melting point metal such as molybdenum (Mo), tungsten (W), or titanium (Ti) or the like or a metal compound containing a high melting point metal. The upper electrode 23 can be a metal compound that contains a metal such as Al, a high melting point metal such as Mo, W, or Ti, or a metal compound that contains a high melting point metal.

As shown in FIG. 21, the thin film piezoelectric resonator 2 of the second embodiment of the present invention has a construction where an opening is formed in the sealing member 19, embedded insulating layer 12, and the semiconductor layer 14 from the bottom of the multilayer construction of the thin film piezoelectric resonator 2, this opening is filled with metal, and the third lead electrode 27 and the fourth lead electrode 28 are connected through a window opening formed in the protective film 18 and through the first lead electrode 22 and the second lead electrode 26.

As shown in FIG. 21, the thin film piezoelectric resonator 2 of the second embodiment of the present invention has a construction where the lead electrodes 27, 28 are retracted from the bottom of the multilayer structure of the thin film piezoelectric resonator 2, and the fine holes 12a for adjusting the resonance frequency are also arranged on the bottom of the multilayer construction of the thin film piezoelectric resonator 2, and therefore argon plasma processing or ion beam etching of the protective film 18 can be performed through the fine holes 12a from the bottom of the multilayer construction of the thin film piezoelectric resonator 2, and therefore resonance frequency upward trimming can be performed by precisely thinning the protective film 18.

On the other hand, with the thin film piezoelectric resonator 2 according to the second embodiment of the present invention, structurally, a weight for adjusting the mass is formed by deposition on the protective film 18, so resonance frequency downward trimming can also be performed. The lead electrodes 27, 28 are positioned beneath the multilayer structure of the thin film piezoelectric resonator 2, so if a deposition layer of a metal such as Au—Sn is formed in order to adjust the mass, the lead electrodes 27, 28 can be covered by an insulating film or the like to prevent electrical short circuits, and therefore the deposition layer of metal such as Au—Sn or the like for adjusting the mass can be formed through the fine holes 12a on just the protective film 18.

Alternatively, with the thin film piezoelectric resonator 2 according to the second embodiment of the present invention, frequency downward trimming can be performed even if an insulating film for adjusting the mass is deposited on the protective film 18 instead of forming a deposition layer of a metal such as Au—Sn or the like for adjusting the mass. In this case, the insulating layer that is deposited on the protective film 18 can also be deposited on the lead electrodes 27, 28, but the insulating layer that is deposited on the lead electrodes 27, 28 should be removed by a subsequent process.

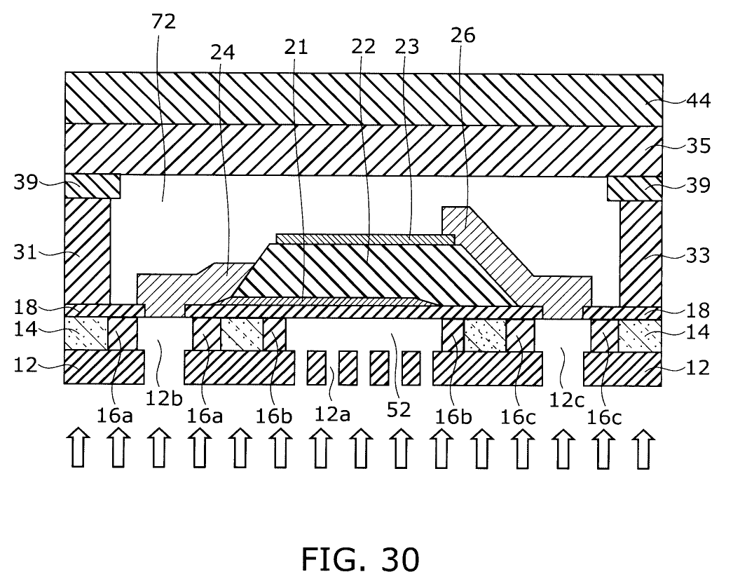

For example, with the construction shown in FIG. 30, which will be described later, frequency downward trimming can be performed by depositing an insulating layer for adjusting the mass on the protective film 18 through the fine holes 112a. In this case, in order to prevent the insulating layer that is deposited on the protective film 18 from also being deposited on the lead electrodes 24, 26 through the openings 12b, 12c, a mask material for example can be placed at the openings 12b, 12c, and this mask material and the deposited insulating layer can be removed together in a subsequent process.

### Manufacturing Method

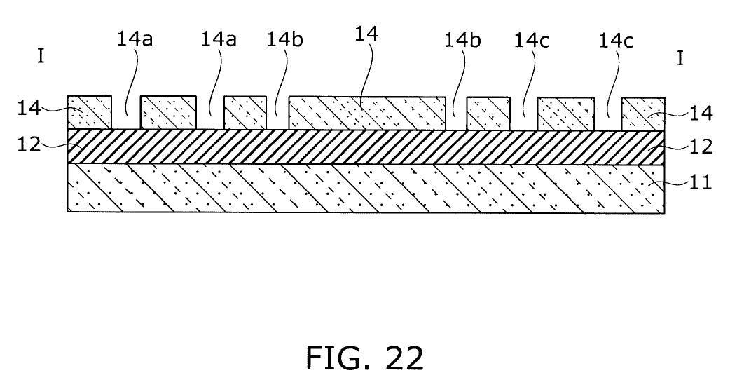

FIG. 22 and FIG. 24 through FIG. 31 schematically show the cross-section structure for explaining one step of the manufacturing method for the thin film piezoelectric resonator according to the second embodiment of the present invention.

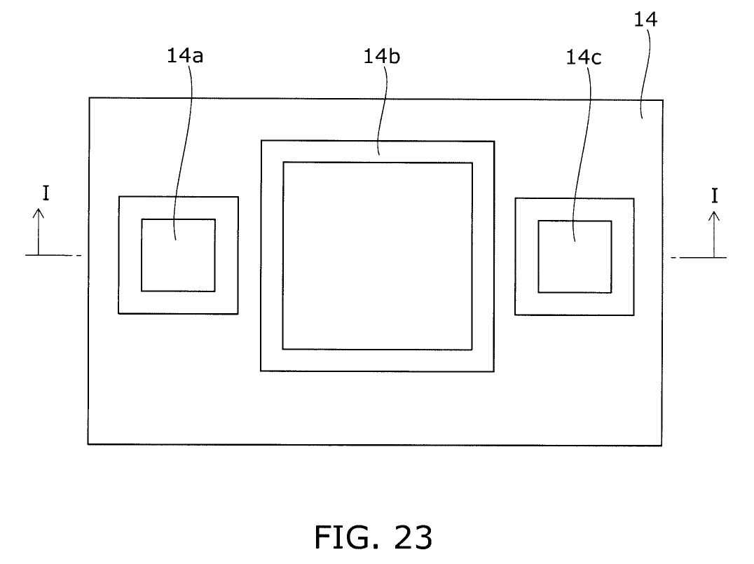

FIG. 23 is a diagram for describing the position of grooves 14a, 14b, and 14c relative to the thin film piezoelectric resonator unit according to the second embodiment of the present invention, wherein the center region shows a groove 14b for designating the lower hollow region of the thin film piezoelectric resonator, pad regions for the lead electrodes 27, 28 on the back surface are designated on the left and the right, where the grooves 14a, 14c for restricting the substrate conductivity are shown. FIG. 22 schematically shows the cross-section construction along line I-I of FIG. 23.

The manufacturing method for the thin film piezoelectric resonator according to the second embodiment of the present invention will be described below while referring to FIG. 22 through FIG. 31.

(A) First, as shown in FIG. 22 and FIG. 23, an embedded insulating layer 12 is formed on a semiconductor substrate 11, a semiconductor layer 14 is formed on the embedded insulating layer 12, and then grooves 14a, 14b, and 14c are formed in the semiconductor layer 14 with a depth that extends to the embedded insulating layer 12. The SOI substrate shown in FIG. 22 can for example be formed using overlaying technology, or can be formed by injecting ions such as oxygen or nitrogen or the like into the semiconductor substrate 11 using SIMOX technology or the like. Alternatively, the semiconductor layer 14 can be formed by depositing polycrystals using crystal growth on the embedded insulating layer 12, and then monocrystalizing the polycrystals using laser annealing technology.

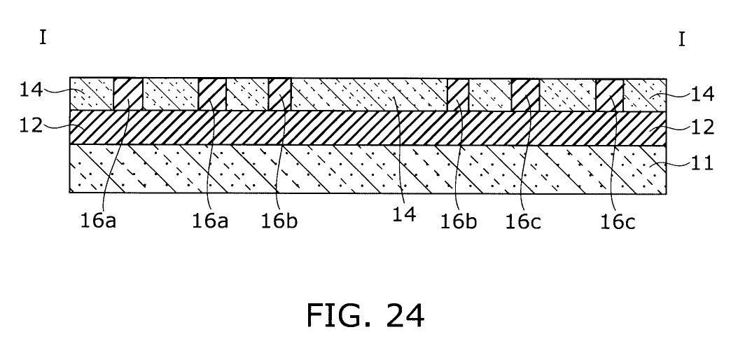

(B) Next, as shown in FIG. 24, the grooves 14a, 14b, 14c are filled with a protective insulating film 16a, 16b, 16c such as a TEOS film or the like, and leveling is performed by CMR

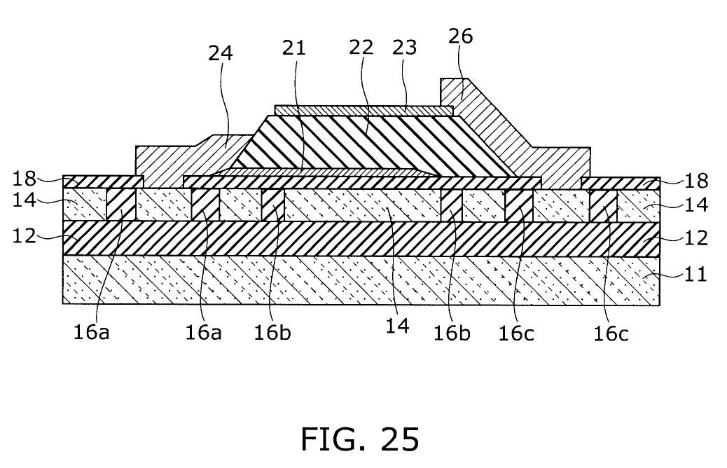

(C) Next, as shown in FIG. 25, a protective layer 18 is deposited, and then the lower electrode 21, piezoelectric film 22, and upper electrode 23 are successively formed on the protective film 18 in order to form the multilayer construction of the thin film piezoelectric resonator. Furthermore, in the region where the lead electrodes 24, 26 are located, a window opening is formed in the protective film 18, and the semiconductor layer 14 is exposed and the lead electrode 24 for the lower electrode 21 and the lead electrode 26 for the upper electrode 23 are formed.

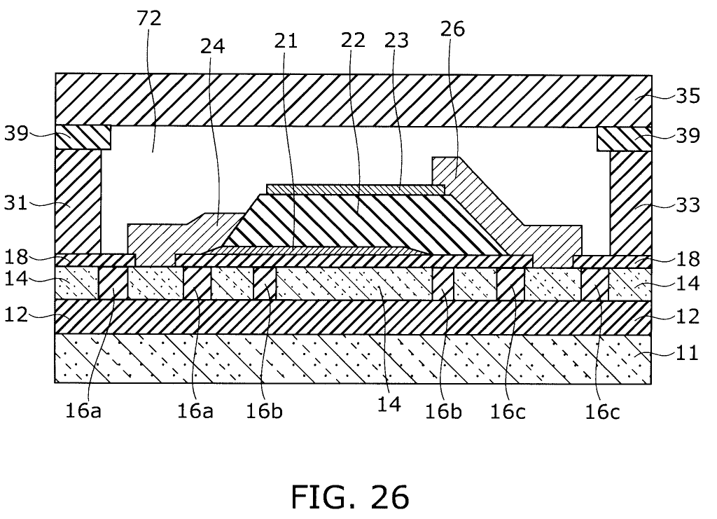

(D) Next, as shown in FIG. 26, supporting parts 31, 33, and sealing members 35, 39 are formed so as to form a cavity 72 located above and protecting the lead electrode 24, piezoelectric film 22, upper electrode 23, and lead electrode 26 on the protective film 18 in the region around the lead electrodes 24, 26. The cavity 72 can for instance be filled with nitrogen or argon or the like. The aforementioned front side sealing process can be performed using a metal hermetic seal as the sealing member 39. Furthermore, the aforementioned process can be performed during the wafer level packaging process.

An insulating substrate can be used as the sealing member 35, or a semiconductor substrate such as silicon can also be used.

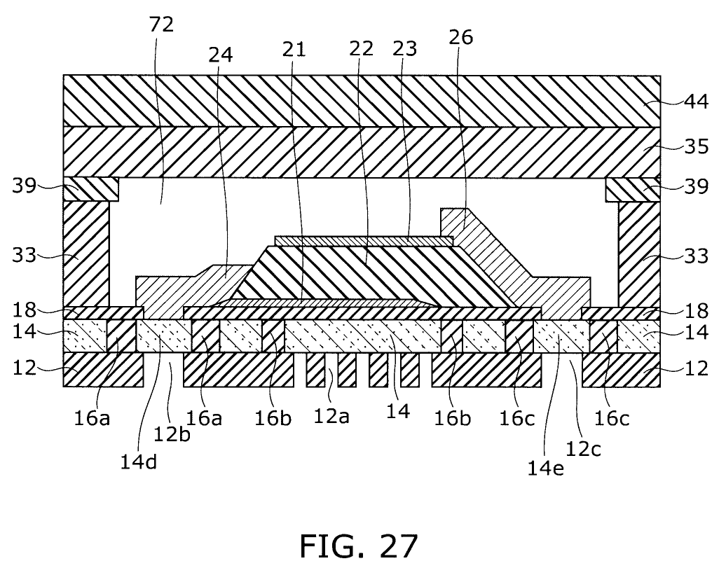

(E) Next, as shown in FIG. 27, front surface protective tape 44 is applied to the sealing member 35, and etching to thin the film is performed on the backside semiconductor substrate 11 until the embedded insulating layer 12 is exposed. For example, wafer thinning is performed to a level of several tens of micrometers or less.

(F) Furthermore, as shown in FIG. 27, fine holes 12a, and openings 12b, 12c are formed in the embedded insulating layer 12 extending to the semiconductor layer 14 using lithography technology and RIE technology. A plurality of fine holes 12a can be formed. Furthermore, as shown in FIG. 27, the position for forming these fine holes 12a is at the bottom of the semiconductor layer 14 that contacts with the protective layer 18 and the protective layer 18 that contacts the lower electrode 21. In other words, a plurality of fine holes 12a may be formed in the region directly below the multilayer structure of the thin film piezoelectric resonator. Furthermore, marks for lithography can be formed when embedding the insulating film and forming the aforementioned grooves. As shown in FIG. 27, the position for forming the openings 12b, 12c is directly below the location that the window opening was formed in the protective film 18 in step (C).

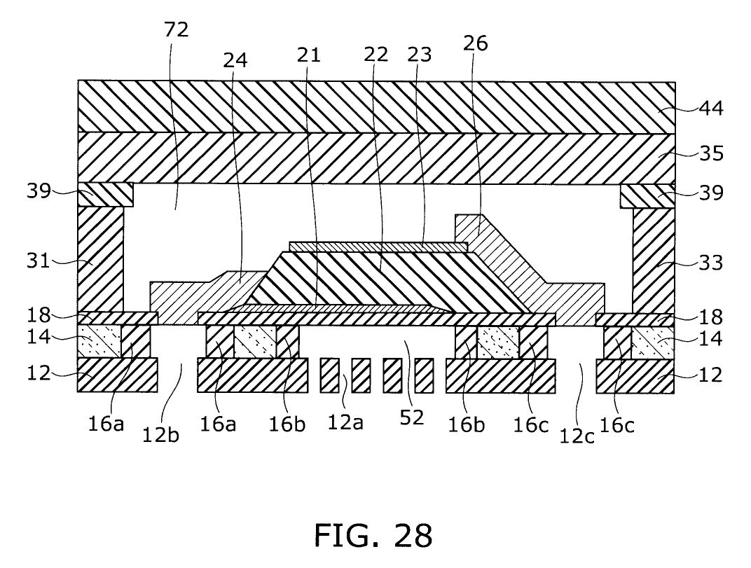

(G) Next, as shown in FIG. 28, the semiconductor layer 14 is selectively removed through the fine holes 12a using anisotropic etching technology such as CDE (Chemical Dry Etching) technology or wet etching technology. Simultaneously, the semiconductor layers 14d, 14e are selectively removed through openings 12b, 12c.

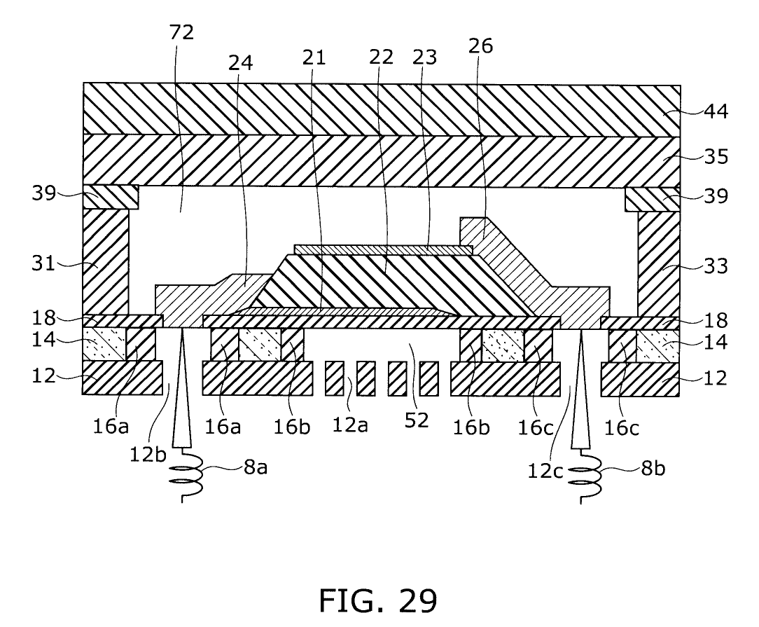

(H) Furthermore, as shown in FIG. 29, the needles of probes 8a and 8b are applied to the lead electrodes 24 and 26 in order to measure the electrical characteristics and frequency characteristics of the thin film piezoelectric resonator. The characteristics are detected to determine whether the values are higher, lower, or equal to the target resonance frequency.

(I) Next, as shown in FIG. 30, the frequency is adjusted by appropriately performing physical etching or physical deposition on the protective film 18 through the fine holes 12a that were first formed in the back surface.

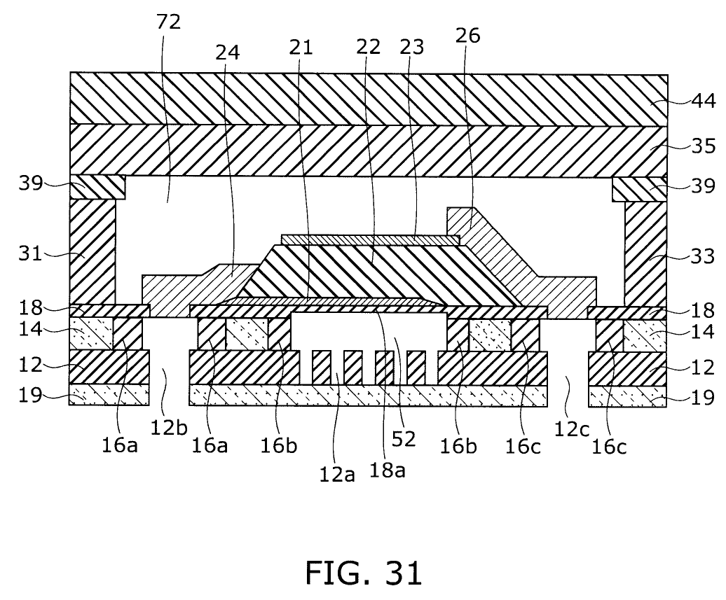

With the manufacturing method for the thin film piezoelectric resonator according to the second embodiment of the present invention, when resonance frequency upward trimming is performed for example, similar to the first embodiment shown in FIG. 17 and FIG. 18, etching of the protective film 18 in the cavity 52 can be performed through the fine holes 12a from the bottom of the multilayer structure of the thin film piezoelectric resonator 2. As a result, similar to the first embodiment shown in FIG. 16, the protective film 18 at the bottom of the multilayer construction of the thin film piezoelectric resonator 2 is made thinner, and a protective film 18a is formed as shown in FIG. 31.

Because etching is performed through the fine hole 12a in this manner, the etching rate can be suppressed to a fraction of the rate when performed directly without passing through the fine holes 12a, and therefore fine adjusting is possible. Furthermore, when resonance frequency downward trimming is performed, the deposition rate can be controlled similarly by being performed through the fine holes 12a, and therefore fine adjustment is possible.

Furthermore, either argon plasma etching or ion beam etching can be applied to the aforementioned etching step. The surface region of the embedded insulating layer 12 into which the fine holes 12a are formed is simultaneously activated and smoothed by this etching step, and this provides the advantage that ambient temperature bonding to the sealing member 19 made from a semiconductor will be simple.

(J) Next, as shown in FIG. 31, after dicing, sealing the hollow on the back surface is completed by directly applying a sealing member 19 made from a semiconductor for instance to the back surface side using bonding technology that uses a glass frit, or ambient temperature bonding technology as shown in FIG. 20, and thereby forming the cavity 52. The cavity 52 can for instance be filled with nitrogen or argon or the like. The aforementioned back surface sealing step can be performed during the wafer level packaging process.

(K) Furthermore, as shown in FIG. 31, openings 12b, 12c are formed in the sealing member 19, and using a mask, lead electrodes 27, 28 are formed by an electroless plating process.

(L) Next, the front surface protective tape 44 is removed, protective tape is applied to the back surface side, the sealing member 35 on the front surface is made thinner by lapping, and then the protective tape on the back surface is removed. As a result, the construction shown in FIG. 21 can be obtained.

With the thin film piezoelectric resonator according to the second embodiment of the present invention as well as the manufacturing method thereof, resonance frequency upward trimming and resonance frequency downward trimming can be performed with good control by physically etching or physically depositing through the fine holes.

### Embodiment 3

As shown in FIG. 21, the thin film piezoelectric resonator according to the third embodiment of the present invention has the same final construction as the thin layer piezoelectric resonator according to the second embodiment, and comprises an embedded insulating layer 12 with fine holes 12a positioned on a sealing member 19, a semiconductor layer 14 with a cavity 52 above the fine holes 12a positioned above the embedded insulating layer 12, a protective film 18 positioned on the semiconductor layer 14 and the cavity 52, a lower electrode 21 located on the protective layer 18, a piezoelectric film 22 located on the lower electrode 21, an upper electrode 23 located on the piezoelectric film 22, a first lead electrode 24 connected to the lower electrode 21 and located on the protective film 18, a second lead electrode 26 that is connected to the upper electrode 23 and is positioned on the protective film 18, a third lead electrode 27 that is connected to the first lead electrode 24 and is located above the protective film 18 on the semiconductor layer 14 side, and a fourth lead electrode 28 connected to the second lead electrode 26 and located above the protective film 18 on the semiconductor layer 14 side.

As shown in FIG. 21, the thin film piezoelectric resonator 2 of the third embodiment of the present invention has a construction where the lead electrodes 27, 28 are retracted from the bottom of the multilayer structure of the thin film piezoelectric resonator 2, and the fine holes 12a for adjusting the resonance frequency are also arranged on the bottom of the multilayer structure of the thin film piezoelectric resonator 2, and therefore argon plasma processing or ion beam etching of the protective film 18 can be performed through the fine holes 12a from the bottom of the multilayer structure of the thin film piezoelectric resonator 2, and therefore resonance frequency upward trimming can be performed by precisely thinning the protective film 18.

On the other hand, with the thin film piezoelectric resonator 2 according to the third embodiment of the present invention, structurally, a weight for adjusting the mass is formed by deposition on the protective film 18, so resonance frequency downward trimming can also be performed. The lead electrodes 27, 28 are positioned beneath the multilayer structure of the thin film piezoelectric resonator 2, so if a deposition layer of a metal such as Au—Sn is formed in order to adjust the mass, the lead electrodes 27, 28 can be covered by an insulating film or the like to prevent electrical short circuits, and therefore the deposition layer of metal such as Au—Sn or the like for adjusting the mass can be formed through the fine holes 12a on just the protective film 18.

Alternatively, with the thin film piezoelectric resonator 2 according to the third embodiment of the present invention, frequency downward trimming can be performed even if an insulating film for adjusting the mass is deposited on the protective film 18 instead of forming a deposition layer of a metal such as Au—Sn or the like for adjusting the mass. In this case, the insulating layer that is deposited on the protective film 18 can also be deposited on the lead electrodes 27, 28, but the insulating layer that is deposited on the lead electrodes 27, 28 should be removed by a subsequent process.

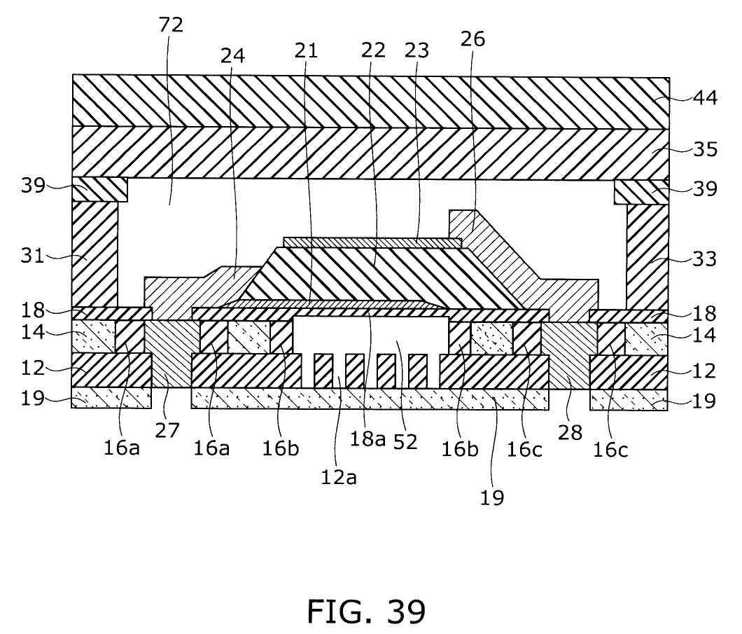

For example, with the construction shown in FIG. 39 which will be described later, frequency downward trimming can be performed by depositing an insulating layer for adjusting the mass on the protective film 18 through the fine holes 12a. In this case, the insulating layer that is deposited on the protective film 18 is also deposited on the lead electrodes 27, 28, but the insulating layer that is deposited on the lead electrodes 27, 28 can easily be removed by a subsequent process.

### Manufacturing Method

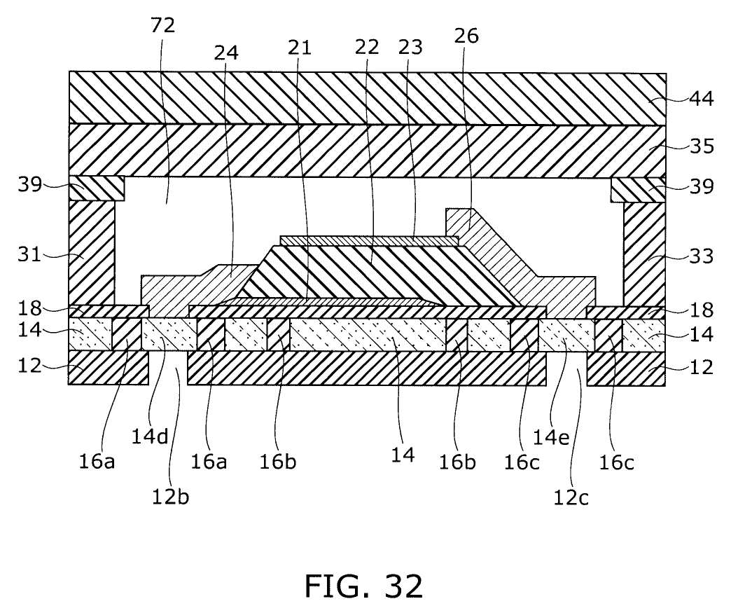

FIG. 32 through FIG. 39 schematically show the cross-section structure for explaining one step of the manufacturing method of the thin film piezoelectric resonator according to the third embodiment of the present invention. The manufacturing method for the thin film piezoelectric resonator according to the third embodiment of the present invention will be described below while referring to FIG. 32 through FIG. 39.

(A) First, similar to the second embodiment as shown in FIG. 22 and FIG. 23 , an embedded insulating layer 12 is formed on a semiconductor substrate 11, a semiconductor layer 14 is formed on the embedded insulating layer 12, and then grooves 14a, 14b, and 14c are formed in the semiconductor layer 14 with a depth that extends to the embedded insulating layer 12. The SOI substrate shown in FIG. 22 can for example be formed using overlaying technology, or can be formed by injecting ions such as oxygen or nitrogen or the like into the semiconductor substrate 11 using SIMOX technology or the like. Alternatively, the semiconductor layer 14 can be formed by depositing polycrystals using crystal growth on the embedded insulating layer 12, and then monocrystalizing the polycrystals using laser annealing technology.

(B) Next, similar to the second embodiment as shown in FIG. 24, the grooves 14a, 14b, 14c are filled with a protective insulating film 16a, 16b, 16c such as a TEOS film or the like, and leveling is performed by CMP.

(C) Next, similar to the second embodiment shown in FIG. 25, a protective film 18 is deposited, and then a lower electrode 21, a piezoelectric film 22, and an upper electrode 23 are successively formed on the protective film 18 in order to form the multilayer structure of the thin film piezoelectric resonator. Furthermore, in the region where the lead electrodes 24, 26 are located, a window opening is formed in the protective film 18, and the semiconductor layer 14 is exposed and the lead electrode 24 for the lower electrode 21 and the lead electrode 26 for the upper electrode 23 are formed.

(D) Next, similar to the second embodiment as shown in FIG. 26, supporting parts 31, 33, and sealing members 35, 39 are formed so as to form a cavity 72 located above and protecting the lead electrode 24, piezoelectric film 22, upper electrode 23, and lead electrode 26 on the protective film 18 in the region around the lead electrodes 24, 26. The cavity 72 can for instance be filled with nitrogen or argon or the like. The aforementioned front side sealing process can be performed using a metal hermetic seal. Furthermore, the aforementioned process can be performed during the wafer level packaging process.

(E) Next, as shown in FIG. 32, front surface protective tape 44 is applied to the sealing member 35, and etching to thin the film is performed on the backside semiconductor substrate 11 until the embedded insulating layer 12 is exposed. For example, wafer thinning is performed to a level of several tens of micrometers or less. Furthermore, as shown in FIG. 32, openings 12b and 12c are formed in the embedded insulating layer 12 extending to the semiconductor layer 14a and 14e using lithography technology and RIE technology. As shown in FIG. 32, the position for forming the openings 12b, 12c is directly below the location that the window opening was formed in the protective film 18 in step (C). Furthermore, marks for lithography can be formed when embedding the insulating film and forming the aforementioned grooves.

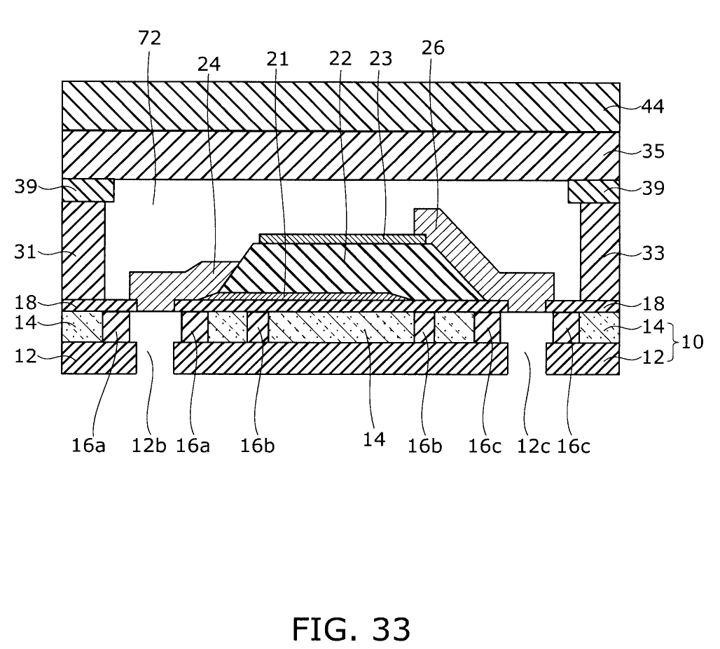

(F) Furthermore, as shown in FIG. 33, the exposed semiconductor layers 14d, 14e are removed by etching until reaching the lead electrodes 24, 26.

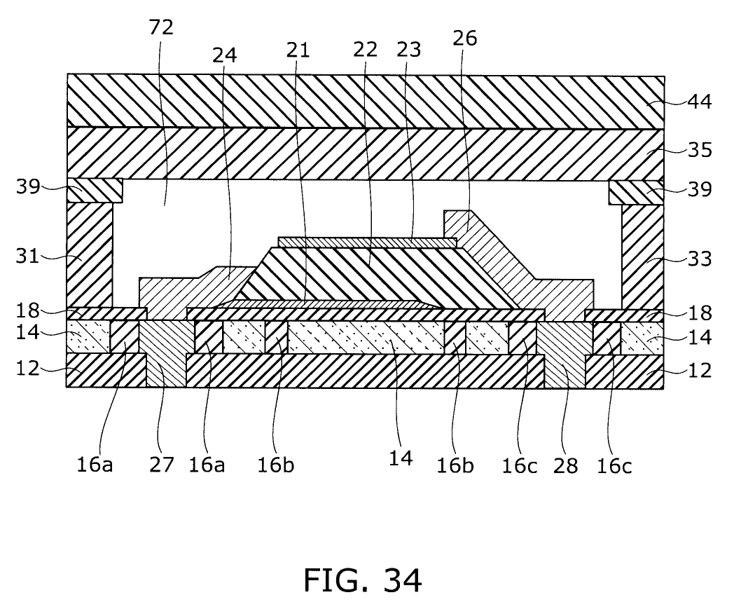

(G) Next, as shown in FIG. 34, using a mask, lead electrodes 27, 28 are formed for instance by an electroless plating process in openings 12b, 12c.

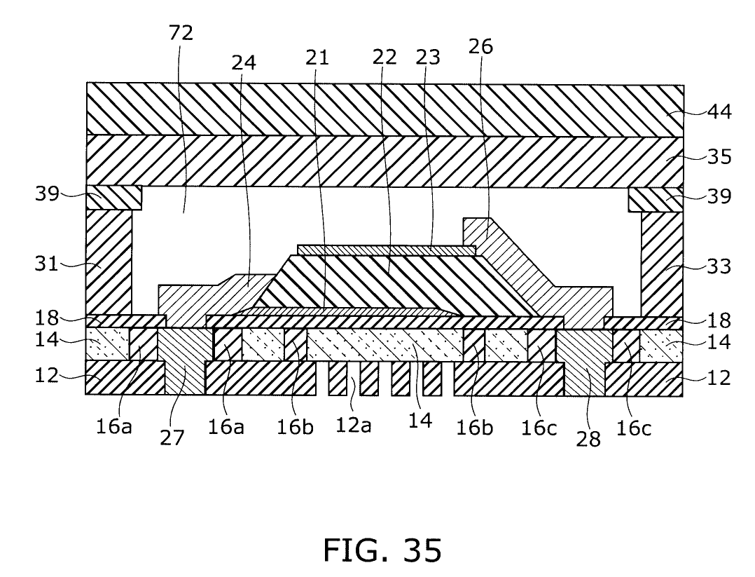

(H) Next, as shown in FIG. 35, fine holes 12a are formed in the embedded insulating layer 12 extending to the semiconductor layer 14 using lithography technology and RIE technology. A plurality of fine holes 12a can be formed. Furthermore, as shown in FIG. 35, the position for forming these fine holes 12a is at the bottom of the semiconductor layer 14 that contacts with the protective layer 18 and the protective layer 18 that contacts the lower electrode 21. In other words, a plurality of fine holes 12a may be formed in the region directly below the multilayer structure of the thin film piezoelectric resonator.

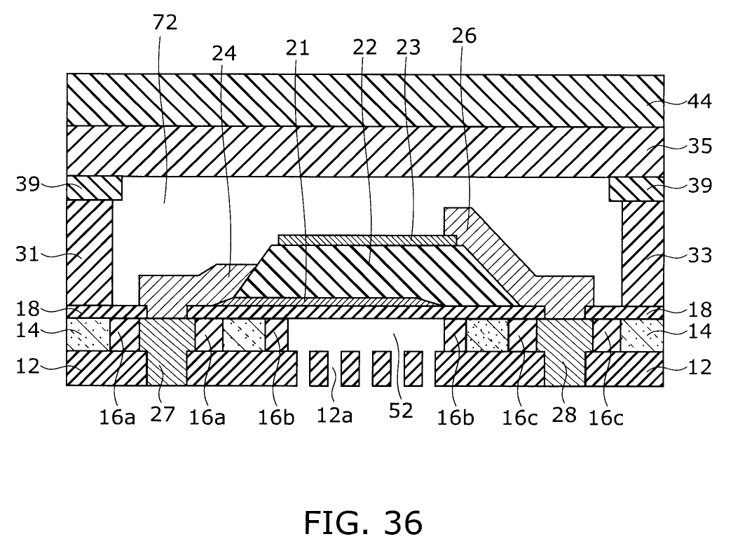

(I) Next, as shown in FIG. 36, the semiconductor layer 14 is selectively removed through the fine holes 12a using anisotropic etching technology such as CDE technology or wet etching technology.

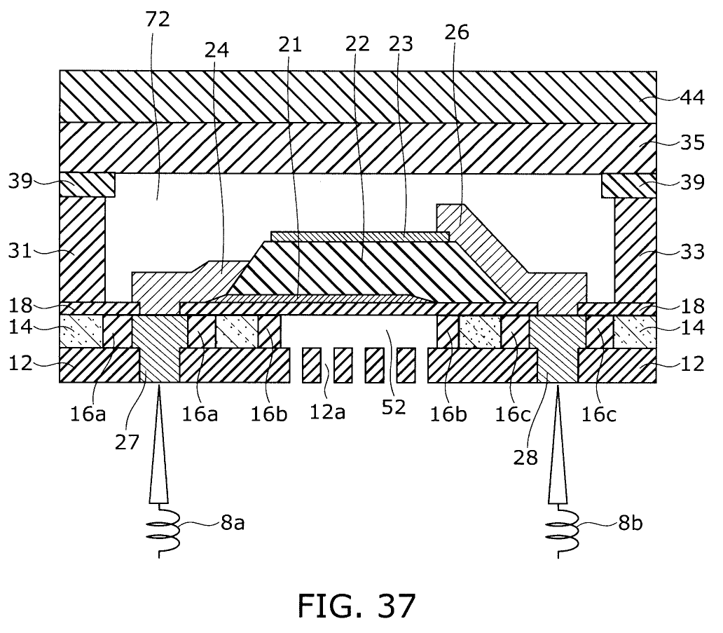

(J) Furthermore, as shown in FIG. 37, the needles of probes 8a and 8b are applied to the lead electrodes 27 and 28 in order to measure the electrical characteristics and frequency characteristics of the thin film piezoelectric resonator. The characteristics are detected to determine whether the values are higher, lower, or equal to the target resonance frequency.

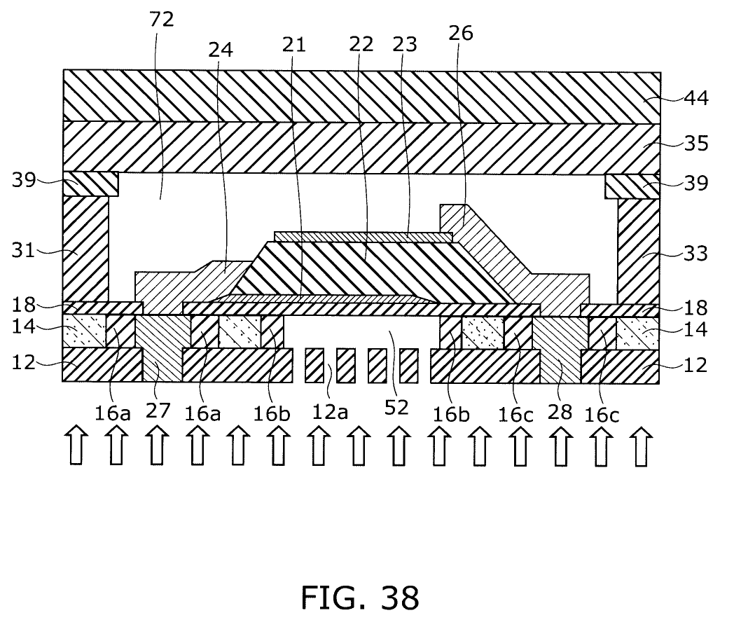

(K) Next, as shown in FIG. 38, the frequency is adjusted by appropriately performing physical etching or physical deposition on the protective film 18 through the fine holes 12a that were first formed in the back surface.

With the manufacturing method for the thin film piezoelectric resonator according to the third embodiment of the present invention, when resonance frequency upward trimming is performed for example, similar to FIG. 17 and FIG. 18 shown in the first embodiment, etching of the protective film 18 in the cavity 52 can be performed through the fine holes 12a from the bottom of the multilayer structure of the thin film piezoelectric resonator 2. As a result, similar to FIG. 16 shown in the first embodiment , the protective film 18 at the bottom of the multilayer structure of the thin film piezoelectric resonator 2 is made thinner, and a protective film 18a is formed as shown in FIG. 39.

Because etching is performed through the fine holes 12a in this manner, the etching rate can be suppressed to a fraction of the rate when performed directly without passing through the fine holes 12a, and therefore fine adjusting is possible. Furthermore, when resonance frequency downward trimming is performed, the deposition rate can be controlled similarly by being performed through the fine holes 12a, and therefore fine adjustment is possible.

Furthermore, in the aforementioned etching step, [missing word] 3 and sealing members 35, 39 are formed for instance by argon plasma etching. The cavity 72 can for instance be filled with nitrogen or argon or the like. The aforementioned front side sealing process can be performed using a metal hermetic seal. Furthermore, the aforementioned process can be performed during the wafer level packaging process.

(E) Next, as shown in FIG. 32, front surface protective tape 44 is applied to the sealing member 35, and etching to thin the film is performed on the backside semiconductor substrate 11 until the embedded insulating layer 12 is exposed. For example, wafer thinning is performed to a level of several tens of micrometers or less. Furthermore, as shown in FIG. 32, openings 12b and 12c are formed in the embedded insulating layer 12 extending to the semiconductor layer 14a and 14e using lithography technology and RIE technology. As shown in FIG. 32, the position for forming the openings 12b, 12c is directly below the location that the window opening was formed in the protective film 18 in step (C). Furthermore, marks for lithography can be formed when embedding the insulating film and forming the aforementioned grooves.

(F) Furthermore, as shown in FIG. 33, the exposed semiconductor layers 14d, 14e are removed by etching until reaching the lead electrodes 24, 26.

(G) Next, as shown in FIG. 34, using a mask, lead electrodes 27, 28 are formed for instance by an electroless plating process in openings 12b, 12c.

(H) Next, as shown in FIG. 35, fine holes 12a are formed in the embedded insulating layer 12 extending to the semiconductor layer 14 using lithography technology and RIE technology. A plurality of fine holes 12a can be formed. Furthermore, as shown in FIG. 35, the position for forming these fine holes 12a is at the bottom of the semiconductor layer 14 that contacts with the protective layer 18 and the protective layer 18 that contacts the lower electrode 21. In other words, a plurality of fine holes 12a may be formed in the region directly below the multilayer structure of the thin film piezoelectric resonator.

(I) Next, as shown in FIG. 36, cavity 52 is formed by selectively removing the semiconductor layer 14 through the fine holes 12a using anisotropic etching technology such as CDE technology or wet etching technology.

(J) Furthermore, as shown in FIG. 37, the needles of probes 8a and 8b are applied to the lead electrodes 27 and 28 in order to measure the electrical characteristics and frequency characteristics of the thin film piezoelectric resonator. The characteristics are detected to determine whether the values are higher, lower, or equal to the target resonance frequency.

(K) Next, as shown in FIG. 38, the frequency is adjusted by appropriately performing physical etching or physical deposition on the protective film 18 through the fine holes 12a that were first formed in the back surface.

With the manufacturing method for the thin film piezoelectric resonator according to the third embodiment of the present invention, when resonance frequency upward trimming is performed for example, similar to as the first embodiment shown in FIG. 17 in FIG. 18, etching of the protective film 18 in the cavity 52 can be performed through the fine holes 12a from the bottom of the multilayer structure of the thin film piezoelectric resonator 2. As a result, similar to the first embodiment shown in FIG. 16, the protective film 18 at the bottom of the multilayer structure of the thin film piezoelectric resonator 2 is made thinner, and a protective film 18a is formed as shown in FIG. 39.

Because etching is performed through the fine holes 12a in this manner, the etching rate can be suppressed to a fraction of the rate when performed directly without passing through the fine holes 12a, and therefore fine adjusting is possible. Furthermore, when resonance frequency downward trimming is performed, the deposition rate can be controlled similarly by being performed through the fine holes 12a, and therefore fine adjustment is possible.

Furthermore, in the aforementioned etching step, the piezoelectric film 22 is made from an AlN film or a ZnO film with excellent [missing word] properties [missing word] for instance argon plasma etching. The lower electrode 21 can be a multilayer metal film such as aluminum (Al) or tantalum aluminum (TaAl) or the like, or a high melting point metal such as molybdenum (Mo), tungsten (W), or titanium (Ti) or the like or a metal compound containing a high melting point metal.

The upper electrode 23 can be a metal compound that contains a metal such as Al, a high melting point metal such as Mo, W, or Ti, or a metal compound that contains a high melting point metal.

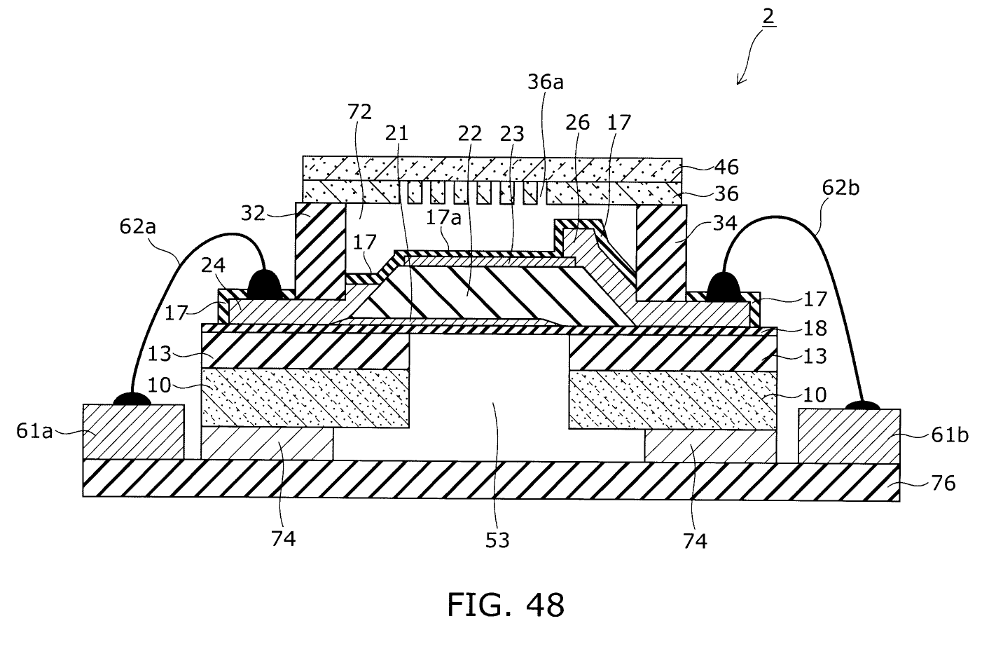

As shown in FIG. 48, the thin film piezoelectric resonator 2 of the fourth embodiment of the present invention has a construction where the lead electrodes 24, 26 are retracted from the top side of the protective film 18 which constitutes the multilayer structure of the thin film piezoelectric resonator 2, and the fine holes 12a for adjusting the resonance frequency are also arranged toward the top of the multilayer construction of the thin film piezoelectric resonator 2, and therefore argon plasma processing or ion beam etching of the protective film 17 can be performed through the fine holes 36a from the top of the multilayer construction of the thin film piezoelectric resonator 2, and therefore resonance frequency upward trimming can be performed by precisely thinning the protective film 17.

On the other hand, with the thin film piezoelectric resonator 2 according to the fourth embodiment of the present invention, structurally, a weight for adjusting the mass is formed by a deposition on the protective film 17, so resonance frequency downward trimming can also be performed. The lead electrodes 24, 26 are positioned above the protective layer 18 which constitutes the multilayer structure of the thin film piezoelectric resonator 2, so if a deposition layer of a metal such as Au—Sn is formed in order to adjust the mass, the lead electrodes 24, 26 can be covered by an insulating film or the like to prevent electrical short circuits, and therefore the deposition layer of metal such as Au—Sn or the like for adjusting the mass can be formed through the fine holes 12a on just the protective film 17.

Alternatively, with the thin film piezoelectric resonator 2 according to the fourth embodiment of the present invention, frequency downward trimming can be performed even if an insulating film for adjusting the mass is deposited on the protective film 17 instead of forming a deposition layer of a metal such as Au—Sn or the like for adjusting the mass. In this case, the insulating layer that is deposited on the protective film 17 can also be deposited on the lead electrodes 24, 26, but the insulating layer that is deposited on the lead electrodes 24, 26 should be removed by a subsequent process.

### Manufacturing Method

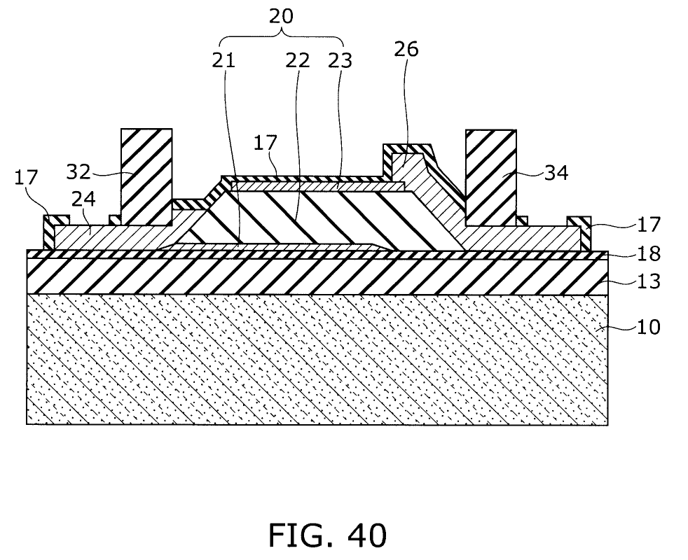

FIG. 40 through FIG. 48 schematically show the cross-section structure for explaining one step of the manufacturing method of the thin film piezoelectric resonator according to the fourth embodiment of the present invention. The manufacturing method for the thin film piezoelectric resonator according to the fourth embodiment of the present invention will be described while referring to FIG. 40 through FIG. 48.

(A) First, as shown in FIG. 40, an insulating layer 13 is formed on a semiconductor substrate 10, a protective film 18 is deposited on the insulating layer 13, and then lower electrode 21, piezoelectric film 22, and upper electrode 23 are successively formed on the protective film 18, thereby forming the multilayer structure of the thin film piezoelectric resonator. Furthermore, a lead electrode 24 is formed for the lower electrode 21 and a lead electrode 26 is formed for the upper electrode 23. Furthermore, after forming the protective layer 17 across the whole surface and making the designated window openings, the supporting parts 32, 34 are formed on the top of the lead electrodes 24, 26.

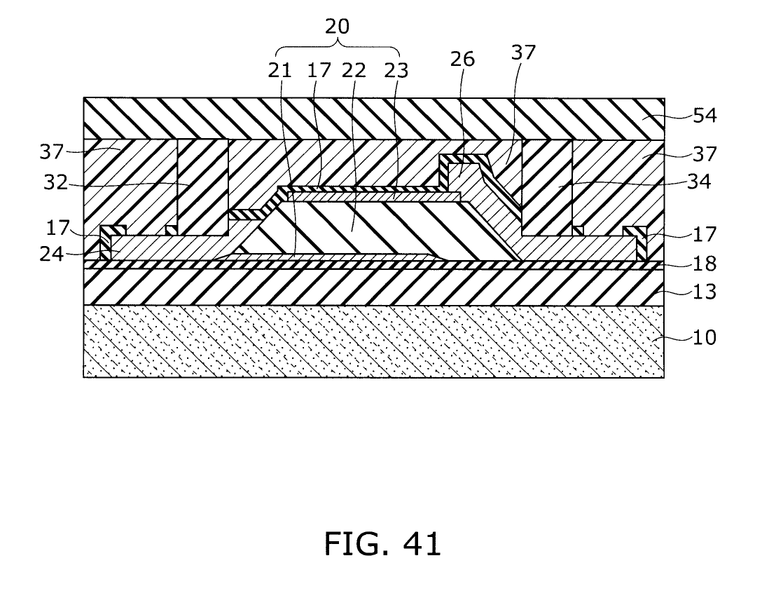

(B) Next, as shown in FIG. 41, a protective resist layer 37 for protecting the surface is deposited on the lead electrode 24, the piezoelectric film 22, the upper electrode 23, and the lead electrode 26, and after leveling and exposing the top surface of the supporting parts 32, 34, a protective foam tape 54 is formed, and then film thinning etching is performed on the semiconductor substrate 10. For example, wafer thinning is performed to a level of several tens of micrometers or less.

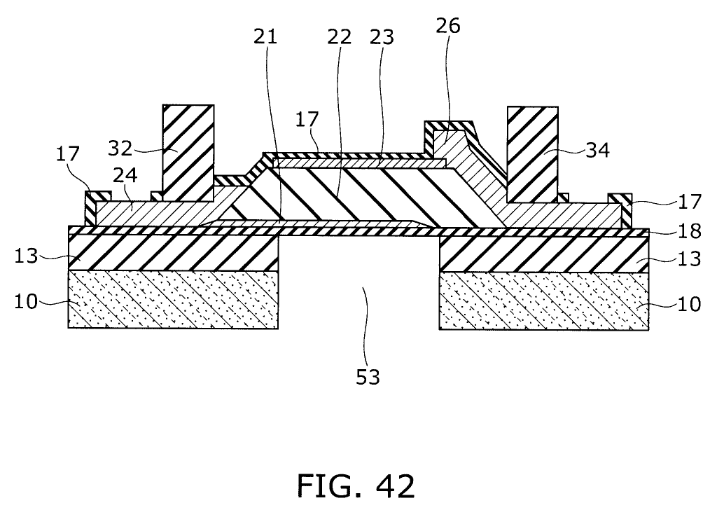

(C) Next, as shown in FIG. 42, an opening 53 that passes through the semiconductor substrate 10 and the insulating layer 13 is formed using lithography and RIE technology, and then the foam tape 54 and a protective resist layer 37 are removed as shown in FIG. 42.

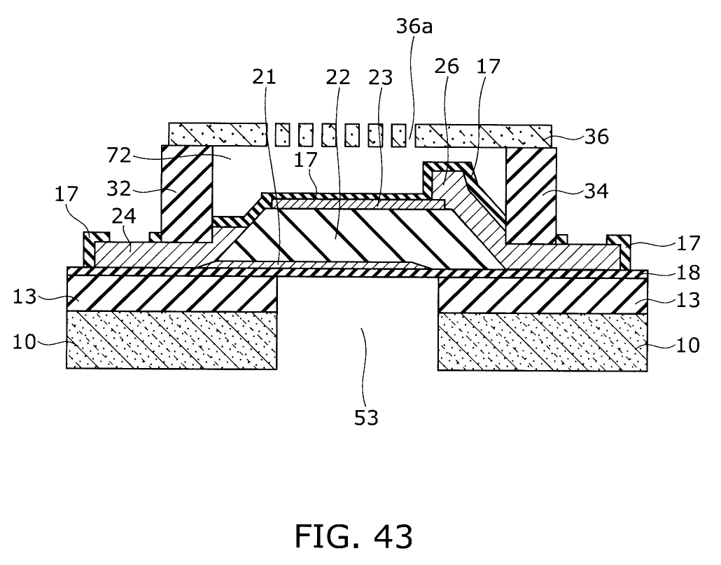

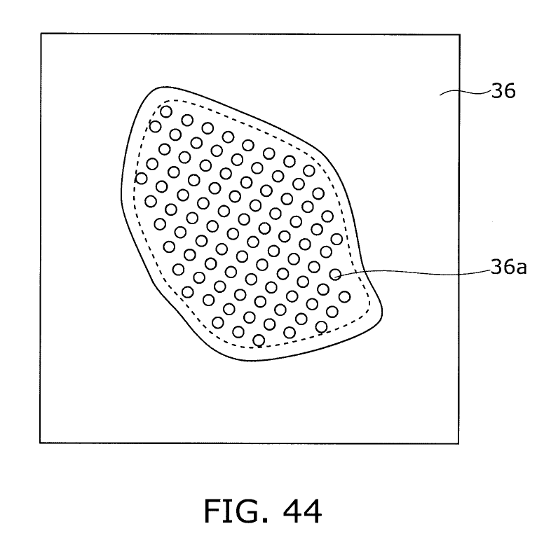

(D) Next, as shown in FIG. 43, an upper member 36 which has fine holes 36a is laid over the supporting parts 32, 34 to form a cavity 72. The upper member 36 can for instance be made from a silicon substrate that can easily be precisely machined. A plurality of fine holes 36a can be formed as shown in FIG. 44. Furthermore, the position that the fine holes 36a are located is above the protective film 17 that is in contact with the upper electrode 23 as shown in FIG. 43. In other words, a plurality of fine holes 36a may be formed in the region directly above the resonator unit.

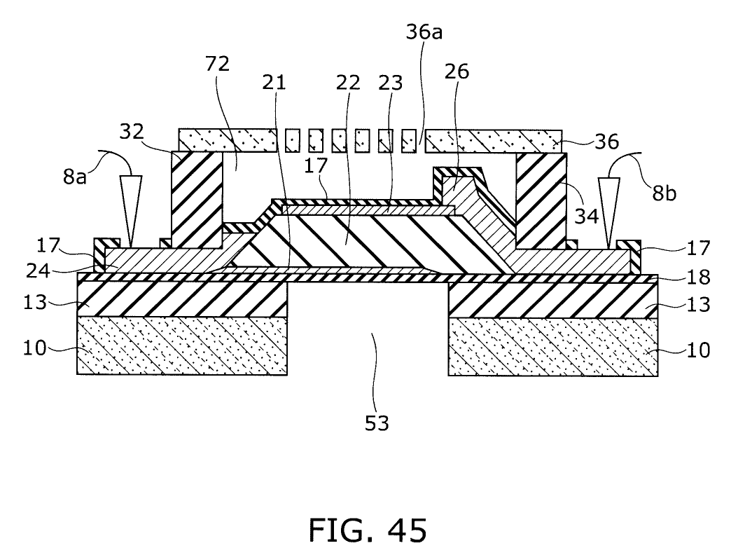

(E) Furthermore, as shown in FIG. 45, the needles of probes 8a and 8b are applied to the lead electrodes 24 and 26 in order to measure the electrical characteristics and frequency characteristics of the thin film piezoelectric resonator. The characteristics are detected to determine whether the values are higher, lower, or equal to the target resonance frequency.

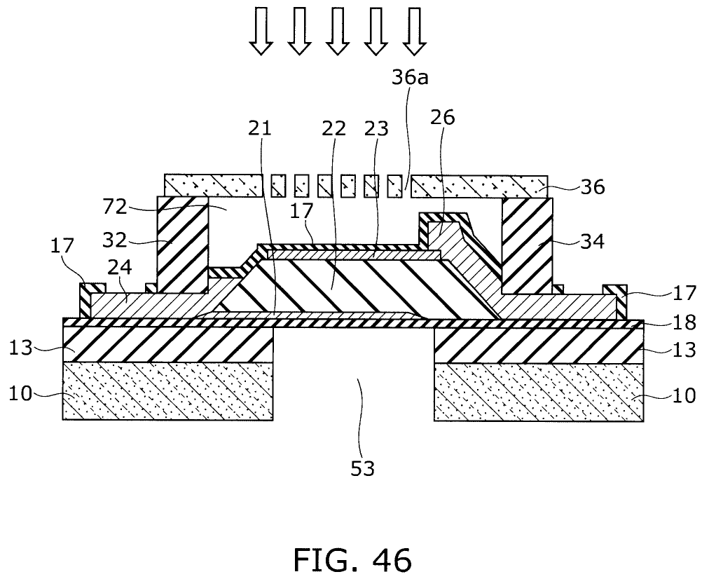

(F) Next, as shown in FIG. 46, the frequency is adjusted by appropriately performing physical etching or physical deposition on the protective film 17 in the cavity 72 through the fine holes 36a.

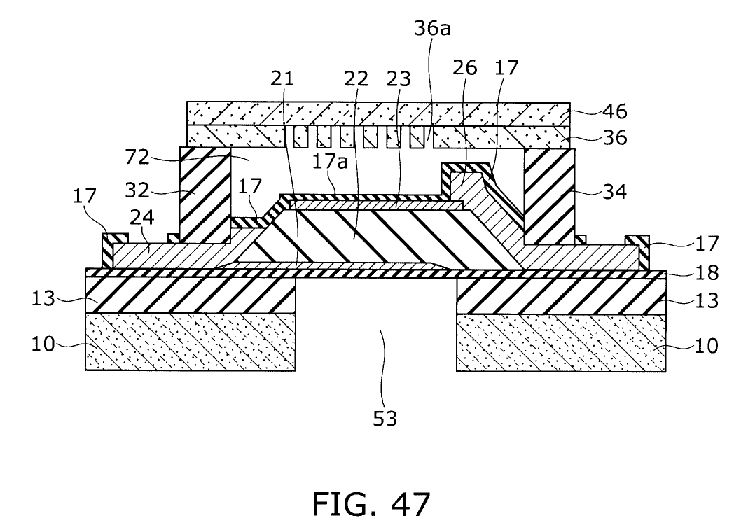

With the manufacturing method for the thin film piezoelectric resonator according to the fourth embodiment of the present invention, if resonance frequency upward trimming process is to be performed, the trimming can be performed by etching the protective layer 17 in the cavity 52 through the fine holes 36a from the top of the multilayer construction of the thin film piezoelectric resonator 2. As a result, as shown in FIG. 47, the protective film 17 opposite the fine hole 36a can be made thinner, forming a protective film 17a at the top of the multilayer structure of the thin film piezoelectric resonator 2. Herein, the shape of the protective film 17a shown in FIG. 47 is a flat layer, but this shape can also be rippled or have protrusions and recesses rather than being flat, reflecting the pattern of the fine holes 36a which are formed in the upper member 36.

Because etching is performed through the fine holes 36a in this manner, the etching rate can be suppressed to a fraction of the rate when performed directly without passing through the fine holes 36a, and therefore fine adjusting is possible. Furthermore, when resonance frequency downward trimming is performed, the deposition rate can be controlled similarly by being performed through the fine holes 36a, and therefore fine adjustment is possible.

(G) Next, as shown in FIG. 47, the sealing member 46 is applied over the upper member 36, and thus the hollow sealing on the front surface side is completed on a wafer level by the supporting parts 32, 34 and the sealing member 46, in order to establish the cavity 72. The cavity 72 can for instance be filled with nitrogen or argon or the like. The support parts 32, 34 can be formed from polyimide or the like. The sealing member 46 can for instance be made from a semiconductor substrate such as silicon 46

(H) Next, as shown in FIG. 48, after dicing, the back surface hollow sealing was completed by directly applying the back surface side to a circuit board 76 using non-flux solder for mounting, thus forming a cavity corresponding to opening 53. This cavity can for instance be filled with nitrogen or argon or the like. Furthermore, wiring 61a was connected to the lead electrode 24, and wiring 61b was connected to the lead electrode 26 using wire for bonding 62a, 62b.

### Resonance Frequency Upward Trimming

With the manufacturing method for the thin film piezoelectric resonator according to the fourth embodiment of the present invention, the resonance frequency upward trimming process can be performed by etching the protective layer 17 in the cavity 72 through the fine holes 36a from the top of the multilayer construction of the thin film piezoelectric resonator 2. As a result, the protective layer 17 at the top of the multilayer structure of the thin film piezoelectric resonator 2 is made thinner, and resonance frequency upward trimming is performed.

If argon plasma processing or ion beam etching is performed on the protective film 17 through the fine holes 36a from the top of the multilayer structure of the thin film piezoelectric resonator 2, the argon plasma processing or the ion beam etching will also be performed simultaneously on the front surface of the upper member 36 into which the fine holes 36a are formed, so there is an advantage that ambient temperature bonds can easily be formed with the upper member 36 because the bonding surface of the adjacent sealing member 46 which is made from a semiconductor will be made smooth by the argon plasma processing or the ion beam etching.

The method for performing the ion beam etching through the fine holes 36a on the protective layer 17 from the top of the multilayer structure of the thin film piezoelectric resonator 2 can be for example the same method as the first embodiment shown in FIG. 17. In other words, the structure of the thin film piezoelectric resonator shown in FIG. 46 is placed in an ion beam etching device, and an ion beam 122 from an argon (Ar) ion beam source 120 is irradiated onto the upper member 36 into which the fine holes 36a are formed, and ion beam etching of the protective layer 17 can be performed with high precision by the portion of the ion beam 122 which passes through the fine holes 36a. Furthermore, the surface of the upper member 36 into which the fine holes 36a are formed is also ion beam etched, and therefore the adjacent sealing member 46 can be bonded by using this activated surface as is.

The method for performing the argon plasma etching through the fine holes 36a on the protective layer 17 from the top of the multilayer structure of the thin film piezoelectric resonator 2 can be for example the same method as the first embodiment shown in FIG. 18. In other words, the construction of the thin film piezoelectric resonator shown in either FIG. 46 is placed on an electrode 126 that is connected to a high-frequency power source 124 that has a frequency of 13.56 MHz, and then plasma etching in an argon (Ar) environment at a pressure between approximately 0.1 and several Pa in the area between the opposing electrode 128, and therefore plasma etching of the protective film 17 can be performed with good precision by the portion of the argon plasma which passes through the fine holes 36a. Furthermore, the surface of the upper member 36 into which the fine holes 36a are formed is also plasma etched, and therefore the adjacent sealing member 46 can be bonded by using this activated surface as is. By applying a direct current bias voltage of several hundred volts to the opposing electrode 128, the argon plasma ions which are generated can be effectively introduced to the surface of the upper member 36 into which the fine holes 36a are formed, and to the surface of the protective film 17 inside the cavity 72.

### Bonding Method

With the manufacturing method for the thin film piezoelectric resonator according to the fourth embodiment of the present invention, the method for performing the bonding of the sealing member 46 to the upper member 36 into which the fine hole 36a are formed can be performed by an ion beam etching method similar to the first embodiment shown in FIG. 20. In other words, the thin film piezoelectric resonator shown in FIG. 46 is placed in an ion beam etching device similar to the first embodiment shown in FIG. 20, and an oblique ion beam 122 from an argon (Ar) ion beam source 120 is irradiated on to the upper member 36 into which the fine holes 36a are formed, and ion beam etching can be performed just on the surface of the upper member 36 into which the fine holes 36a are formed. In this case, the surface of the upper member 36 into which the fine holes 36a were formed will be ion beam etched, so bonding to the adjacent sealing member 46 is possible using the activated surface as is, but similar to the first embodiment shown in FIG. 20, the oblique ion beam 122 from the argon (Ar) ion beam source 120 is simultaneously irradiated onto the surface of the sealing member 46, and therefore the sealing member 46 and the upper member 36 and which the fine hole 36a are formed can effectively be ambient temperature bonded because the surface of the sealing member 46 has also be an activated.

With the thin film piezoelectric resonator according to the fourth embodiment of the present invention as well as the manufacturing method thereof, resonance frequency upward trimming and resonance frequency downward trimming can be performed with good control by physically etching or physically depositing through the fine holes.

### EXAMPLES OF APPLICATION

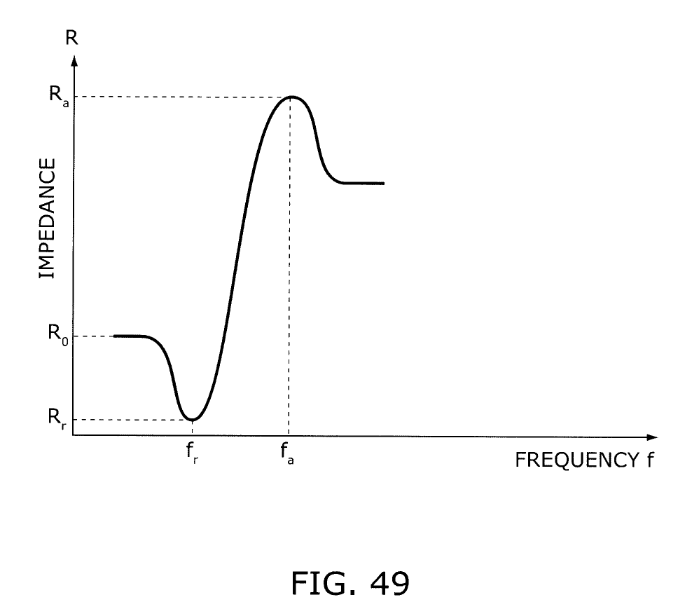

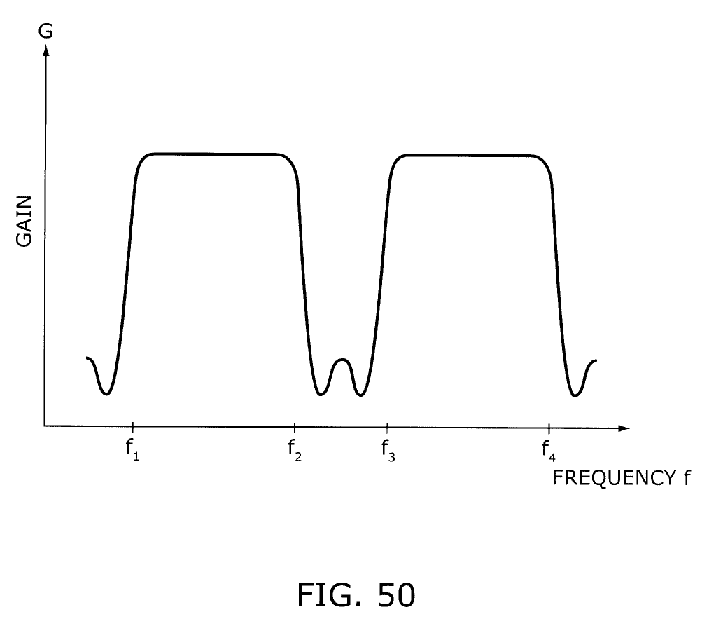

The frequency characteristic of impedance R of the thin film piezoelectric resonator according to the first through fourth embodiments of the present invention can be schematically presented for example as shown in FIG. 49. In other words, at a given resonance frequency of fr and an antiresonance frequency of fa for a direct current impedance of Ro, an impedance of for example Rr is obtained during resonance and an impedance of for instance Ra is obtained during anti-resonance. By combining a plurality of thin film piezoelectric resonators with this frequency characteristic, as shown in FIG. 50, a bandpass filter can be constructed which has minimal losses between frequencies f1 and f2 as well is between f3 and f4. The thin film piezoelectric resonator and the pads can have various shapes and arrangements.

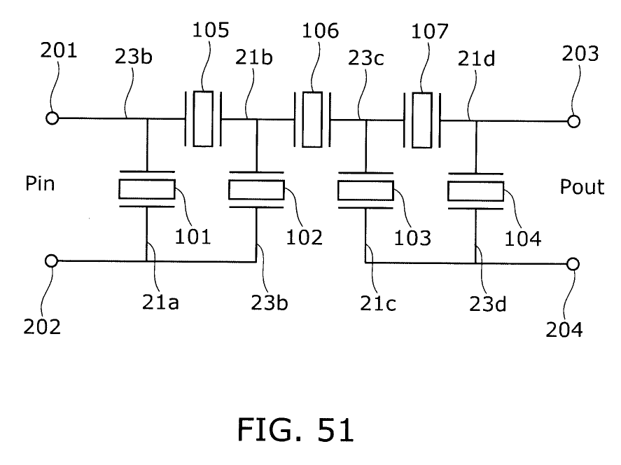

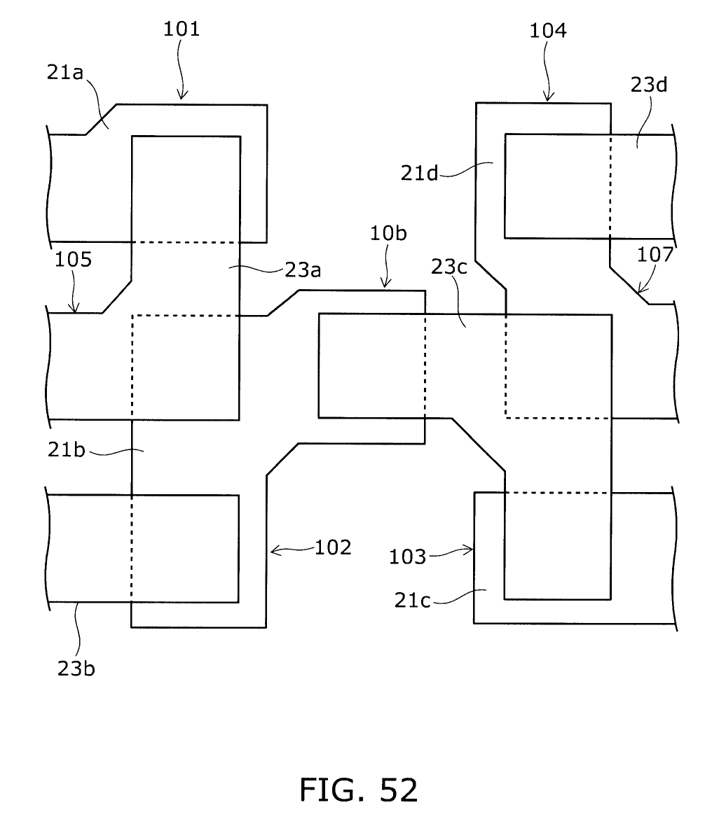

As an application example, the example of the filter will be described below, but the application examples of the present invention are not restricted to filters, and other circuits such as oscillator circuits or the like can also be applicable. Furthermore, the construction of the filter shown in FIG. 51 and FIG. 52 is an example, but the present invention is not restricted to FIG. 51 and FIG. 52, and various other forms are possible for the number of stages and the connecting relationship with the thin film piezoelectric resonator.

FIG. 51 shows an example of a high-frequency filter according to an application example of the present invention which has a construction with seven thin film piezoelectric resonators 101, 102, 103, 104, 105, 106, and 107. The seven thin film piezoelectric resonators 101 through 107 are arranged and connected in series-parallel as shown in FIG. 51. The high-frequency filter is a 3.5 stage ladder-type filter with thin film piezoelectric resonators 105, 106, and 107 as the series resonators and thin film piezoelectric resonators 101, 102, 103, and 104 as the parallel resonators.

As shown in FIG. 52, the high-frequency filter has a pattern wherein the upper electrode wiring 23a that is electrically connected to one terminal 201 of an input port pin acts as the upper electrode for both the thin film piezoelectric resonator 101 and the thin film piezoelectric resonator 105. The lower electrode wiring 21a that is electrically connected to the other terminal 202 of the input board pin functions as the lower electrode for the thin film piezoelectric resonator 101.

The lower electrode wiring 21b of the thin film piezoelectric resonator 105 is patterned as the lower electrode for both thin film piezoelectric resonators 102 and 106. The thin film piezoelectric resonator 102 has a pattern where the upper electrode wiring 23b is electrically connected to the other terminal 202 of the input port pin. Furthermore, the lower electrode wiring 21b is arranged in a pattern as the lower electrode common for the thin film piezoelectric resonators 105, 102, and 106.

The upper electrode wiring 23c is patterned to the three thin film piezoelectric resonators 106, 107, and 103 as the upper electrode common for the three thin film piezoelectric resonators 106, 107, and 103. For the thin film piezoelectric resonator 103, the lower in electrode wiring 21c is patterned to be electrically connected to one terminal 204 of the output port Pout. The lower electrode wiring 21d that is electrically connected to the other terminal 203 of the output port Pout is patterned as the lower electrode common for the thin film piezoelectric resonator 107 and the thin film piezoelectric resonator 104. For the thin film piezoelectric resonator 104, the upper electrode wiring 23d is patterned to be electrically connected to one terminal 204 of the output port Pout. Herein, the lower electrode wirings 21a, 21b, 21c, 21d and the upper electrode wirings 23a, 23b, 23c, and 23d shown in FIG. 52 may be wholly formed on the protective layer 18 similar to the first embodiment, or may be retractable in the downward direction of the thin film piezoelectric resonator through the window openings which are established in the protective film 18 as with the second and third embodiments.

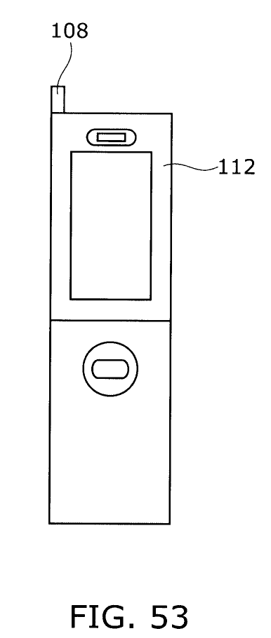

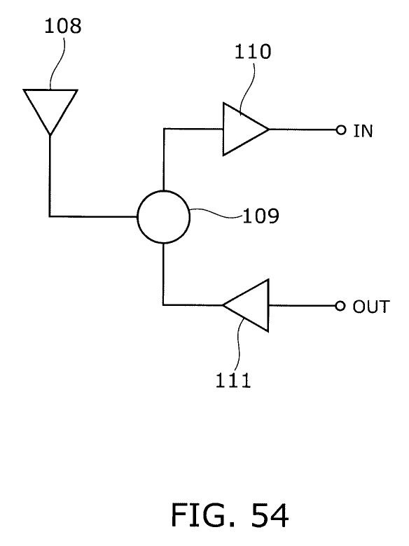

An example where two of these bandpass filters are formed has the characteristics shown in FIG. 50. An application example of the bandpass filter shown in FIG. 50 is a duplexer 109 that is built into a mobile phone 112 as shown in FIG. 53. In other words, as shown in FIG. 54, when a signal is received, the signal received by the antenna 108 is passed through a duplexer 109 and is amplified in a low noise amp (LNA). On the other hand, audio output is amplified by a power amp (PA) 111, passed through the duplexer 109, and transmitted from the antenna 108.

The signal which passes through the duplexer 109 selects the frequency band for the input output signal in order to prevent mixed signals, and the thin film piezoelectric resonator 2 according to the embodiment of the present invention can be used in the circuit component shown in FIG. 51 as a bandpass filter for this application.

### OTHER EMBODIMENTS

As shown above, the present invention was shown by the embodiment, but the drawings and descriptions which form a part of this disclosure must not be interpreted as limiting the present invention. Various alternate embodiments, applications, and applicable technologies will be obvious from this disclosure to one skilled in the art.

For example, a semiconductor device containing a portion of the construction that was described in the embodiment's can be similarly constructed. Therefore, the present invention of course includes various other embodiments or the like which are not shown herein therefore, the technical scope of the present invention shall be determined only by the specific items of the invention shown in the patent claims which are applicable to the aforementioned descriptions.

1. A thin film piezoelectric resonator, comprising:
a sealing member;
an insulating layer with fine holes which is provided on the sealing member;
a semiconductor layer which has a cavity over the fine holes provided on the insulating layer;
a protective film provided on the semiconductor layer and over the cavity;
a lower electrode provided on the protective film;
a piezoelectric film provided on the lower electrode;
an upper electrode provided on the piezoelectric film;
a first lead electrode connected to the lower electrode and provided on the protective film;
a second lead electrode connected to the upper electrode and provided on the protective film; and
an etched part of the protective film or a deposited layer part which is formed opposite the fine holes.

2. The thin film piezoelectric resonator according to claim 1, further comprising:
a third lead electrode which is extended to a sealing member side and is connected to the first lead electrode through a window opening in the protective film; and
a fourth lead electrode which is extended to a sealing member side and is connected to the second lead electrode through a window opening in the protective film.

3. The thin film piezoelectric resonator according to claim 1, wherein a thickness of the protective film etching region is thinner than a thickness of a region of the protective film which is not exposed in the cavity.

4. The thin film piezoelectric resonator according to claim 1, wherein the deposition layer is made of metal.

5. The thin film piezoelectric resonator according to claim 1, wherein the deposition layer is made of an insulating material.

6. The thin film piezoelectric resonator according to claim 1, wherein the sealing member and the insulating layer are bonded by a deposition layer of bonding material.

7. A thin film piezoelectric resonator, comprising:
a lower electrode;
a piezoelectric film provided on the lower electrode;
an upper electrode provided on the piezoelectric film;
a protective film provided on the upper electrode;
an upper member having fine holes provided on the protective layer with a cavity therebetween;
a sealing member which seals the cavity and is provided on the upper member; and
an etched part of the protective film or a deposited layer part which is formed opposite the fine holes.

8. The thin film piezoelectric resonator according to claim 7, wherein a thickness of the protective film etching region is thinner than a thickness of a region of the protective film which is not exposed in the cavity.

9. The thin film piezoelectric resonator according to claim 7, wherein the deposition layer is made of metal.

10. The thin film piezoelectric resonator according to claim 7, wherein the deposition layer is made of an insulating material.

11. The thin film piezoelectric resonator according to claim 7, wherein the sealing member and the insulating layer are bonded by a deposition layer of bonding material.

12. A manufacturing method for a thin film piezoelectric resonator, comprising:
forming a structure having a multilayer structure including a first protective film, a lower electrode, a piezoelectric film, an upper electrode and a second protective film in this order, a first lead electrode connected to the lower electrode, a second lead electrode connected to the upper electrode, and a member having fine holes opposite to the multilayer structure with a cavity therebetween; and
measuring a frequency characteristics between the first and second lead electrodes and if the measured frequency is low or high, forming an etched part of a first protective film provided below the multilayer structure or of a second protective film on the multilayer structure, or a deposited layer part on a first protective film provided below the multilayer structure or on a second protective film on the multilayer structure, opposite the fine holes.

13. The manufacturing method for a thin film piezoelectric resonator according to claim 12, wherein the forming the structure includes:
forming a multilayer structure including the lower electrode, the piezoelectric film, and the upper electrode, and forming the first lead electrode which is connected to the lower electrode and the second lead electrode which is connected to the upper electrode, and forming the cavity which is connected to an outside by the fine holes, under the lower electrode or on the upper electrode.

14. The manufacturing method for a thin film piezoelectric resonator according to claim 12, wherein the forming the structure includes:
forming a groove in a surface of a semiconductor in which an insulating layer is embedded, the groove extending to the insulating layer;
filling the groove with a protective insulating film, smoothing a surface thereof, depositing the first protective film, successively forming the lower electrode, the piezoelectric film, and the upper electrode on the first protective film;
thinning the semiconductor until the insulating layer is exposed from a back surface thereof;
forming the fine holes in the insulating layer at a bottom of the lower electrode, the fine holes extending to the semiconductor on a front surface side from the insulating layer; and
forming the cavity by selectively removing a region of the semiconductor on the front surface side which is demarcated by the protective insulating film through the fine holes.

15. The manufacturing method for a thin film piezoelectric resonator according to claim 12, further comprising hermetically sealing the cavity by blocking the fine holes, after forming the etched part or deposited layer part.

16. The manufacturing method for a thin film piezoelectric resonator according to claim 12, wherein the etched part is formed by argon plasma processing or ion beam etching through the fine holes.

17. The manufacturing method for a thin film piezoelectric resonator according to claim 12, wherein the deposited layer part is formed by depositing a metal or insulating material through the fine holes.

18. The manufacturing method for a thin film piezoelectric resonator according to claim 12, further comprising bonding the member having fine holes and the sealing member using a deposition layer of bonding material, after forming the etched part or the deposited layer part.

19. The manufacturing method for a thin film piezoelectric resonator according to claim 7, further comprising irradiating an ion beam onto a bonding surface of the member having the fine holes and a bonding surface of the sealing member, and then bonding the bonding surface of the member having the fine holes and the bonding surface of the sealing member, after forming the etched part or the deposited layer part.

20. The manufacturing method for a thin film piezoelectric resonator according to claim 7, wherein the structure includes a reinforced tape which is bonded to the member having the fine holes, and the forming the etched part or the deposited layer part includes removing the reinforced tape.
